(19) United States
(12) Patent Application Publication
(10) Pub. No.: US 2026/0269846 A1
(43) Pub. Date: Sep. 10, 2026

(54) QUANTIZED AMPLIFICATION WITH REDUCED NUMBER OF PASSBAND MODULATORS

(71) Applicant: QDAComm LLC, Raleigh, NC (US)

(72) Inventors: Paulo Carvalho, Lisboa (PT); Rui Dinis, Costa da Caparica (PT)

(73) Assignee: QDAComm LLC, Raleigh, NC (US)

(21) Appl. No.: 19/072,638

(22) Filed: Mar. 6, 2025

(51) Int. Cl. H04B 1/00; H03M 3/00; H04B 1/40

(52) U.S. Cl. CPC H04B 1/0007; H03M 3/43; H04B 1/40

(57) ABSTRACT

Systems and methods of performing quantized amplification with a reduced set of bandpass modulators are provided. In one exemplary embodiment, a user equipment device includes a set of bandpass modulator circuitry operable to output a punctured set of bandpass components that collectively represents a sample of an input signal having information and a set of power amplifier circuitry electrically coupled to the set of bandpass modulator circuitry and operable to amplify the punctured set of bandpass components. Further, the punctured set of bandpass components corresponds to the set of power amplifier circuitry and is associated with a set of quantized bits that represents a quantized amplitude of a polar representation of the input signal sample.

### FIELD OF DISCLOSURE

The present disclosure relates generally to the field of communications and more specifically to quantized amplification with a reduced set of bandpass modulators.

### BACKGROUND

A fundamental component of a wireless communications system is the transceiver front-end which includes power amplifier circuitry. The transceiver front-end, which can include a digital baseband subsystem and an analog radio frequency (RF) subsystem, can convert digital baseband samples representing an input signal to an analog baseband signal and can then modulate the analog baseband signal and up-convert the modulated signal to an RF carrier. In this process, digital-to-analog converter (DAC) circuitry in the transceiver subsystem can convert the digital baseband samples to the analog baseband signal. In telecommunications systems, improved energy efficiency is a common requirement, especially in wideband communication systems employing single carrier or multicarrier modulations with higher spectral efficiencies (e.g., large constellations), in which envelope fluctuations can compromise power amplification efficiency by a power amplifier (PA) in the transceiver front end. The Background section of this document is provided to place embodiments of the present disclosure in technological and operational context, to assist those of skill in the art in understanding their scope and utility. Unless explicitly identified as such, no statement herein is admitted to be prior art merely by its inclusion in the Background section.

### BRIEF SUMMARY OF THE DISCLOSURE

The following presents a simplified summary of the disclosure in order to provide a basic understanding to those of skill in the art. This summary is not an extensive overview of the disclosure and is not intended to identify key/critical elements of embodiments of the disclosure or to delineate the scope of the disclosure. The sole purpose of this summary is to present some concepts disclosed herein in a simplified form as a prelude to the more detailed description that is presented later.

Briefly described, embodiments of the present disclosure relate to systems and methods of performing quantized amplification with a reduced set of bandpass modulators. According to one aspect, a method can include: receiving samples of a baseband signal or samples of in-phase and quadrature-phase components of the baseband signal, receiving an input clock signal according to the sampling frequency fₛ=1/T_{S} of the baseband signal, receiving a clock signal according to an intermediate frequency fᵢ, or receiving a clock signal in accordance with the carrier frequency f_{c} of the output signal. The method can further include receiving, by a quantizer circuitry, the samples of sₙ of the baseband signal sₙ=s(tₙ)=s_{I,n}+js_{Q,n}, with tₙ being the sampling instant. The method can further include computing

$${A}_{n} = \sqrt{{s}_{I , n}^{2} + {s}_{Q , n}^{2}} , {α}_{n} = A TAN ( {s}_{Q , n} / {s}_{I , n} ) ,$$

and can include quantizing Aₙ based on a quantization encoding table representing N_{b} bits, a table with a finite set of quantization values and a table with the discrete amplitudes of the quantization components aᵢ={a₁, a₂, . . . , a_{Nb}} in which the quantized value can be decomposed. The method can further include obtaining, by the quantizer circuitry, the quantized value A_{qn}=Aₙ+e_{q}, where e_{q} denotes the quantization error. The method can further include obtaining a set of quantization bits and determining a compensation factor Δ belonging to a finite discrete alphabet based on the quantization error e_{q}. The method can further include determining, by a punctured encoder circuitry, a punctured encoding table of a quantization encoding table. The method can further include obtaining, by the punctured encoder circuitry, a set of N′≤N_{b} active pairs of in-phase and quadrature-phase mapping components based on the punctured encoding table of the quantization encoding table, the amplitude Aₙ and the phase αₙ of the sample, and the quantization bits. In one example, the mapping table can be stored in a Look-Up Table (LUT) circuitry that includes the mapping components values according to a puncturing rule and may include the quantization bits combinations, the sets of discrete amplitudes aᵢ, or the set of quantized values. The method can further include selecting, by the punctured encoder circuitry, the mapping coefficients Cₖ, k=1, . . . , N_{b} based on the quantization bits and the punctured encoding, with the mapping coefficients Cₖ, k=1, . . . , N_{b} being configured to map the quantized value into N′≤N_{b} pairs of in-phase s_{I,n} and quadrature-phase s_{Q,n} mapping components represented by Cₖ cos(αn) and Cₖ sin(αn) with k=1, . . . , N_{b}. The mapping amplitude coefficients Cₖ can represent values from N_{b} discrete alphabets. The method can further include outputting, by the punctured mapper circuitry, to each bandpass modulator circuitry two different sets of mapping coefficients corresponding to the two possible bandpass components that can be generated.

According to another aspect, the method can further include receiving, by a set of N′ bandpass modulator circuitry, N′ pairs of in-phase and quadrature-phase mapping components to obtain N′ active bandpass components. The set of N′ bandpass modulator circuitry can include a set of in-phase and quadrature-phase (I/Q) modulator circuitry or a set of I/Q DAC circuitry.

According to another aspect, with the value of N_{b} being an odd number, the maximum number of active mapping components can be

$${N}^{′} = \frac{{N}_{b} + 1}{2}$$

and the maximum number of bandpass modulators can be reduced to N′.

According to another aspect, with the value of N_{b} being an even number, the maximum number of active mapping components can be

$${N}^{′} = \frac{{N}_{b}}{2}$$

and the maximum number of bandpass modulators can be reduced to

$$\frac{{N}_{b}}{2} .$$

According to another aspect, the method can further include determining control information based on the mapping rule applied to each quantized value, with the control information being configured to activate mapping components, activate switches, or activate power amplifiers operable to amplify the punctured set of bandpass components.

According to another aspect, each of the set of bandpass modulator circuitry can be implemented by an I/Q DAC or an I/Q modulator circuitry.

According to another aspect, the method can further include outputting, by the punctured mapper circuitry, to the set of active bandpass modulators (e.g., I/Q modulator circuitry, I/Q DAC) the phase αₙ of each sample to enable control of the initial phase of the sinusoidal signals obtained by the punctured set of bandpass components for each sampling interval.

According to another aspect, the method can further include modulating, by the set of bandpass modulator circuitry, a set of active bandpass components at the intermediate frequency fᵢ. Further, the method can include upconverting, by a set of mixer circuitry, the N′ active bandpass components at the carrier frequency f_{c}.

According to another aspect, each of the set of bandpass modulator circuitry is associated with more than two different sets of mapping coefficients, output by the punctured mapper circuitry, which correspond to the possible bandpass components that can be generated.

According to another aspect, the method can further include outputting, by the punctured mapper circuitry, information configured to control the initial phase of bandpass components output by the set of bandpass modulator circuitry (e.g., I/Q modulator circuitry, I/Q DAC), which can be determined by modifying the phases or delays of the inputs to the set of bandpass modulator circuitry at the beginning of each sampling interval.

According to another aspect, the method and apparatus for quantized amplification with a reduced set of bandpass modulators can include processing, by each bandpass modulator, a corresponding active pair of in-phase and quadrature-phase mapping components to obtain N′<Nb active intermediate frequency (IF) bandpass components that are input to a set of N′ mixer circuitry to upconvert and obtain N′ bandpass components.

According to another aspect, the method and apparatus for quantized amplification with reduced number of bandpass modulators can include digital circuitry that computes Aₙ, αₙ, quantizes Aₙ, performs punctured encoding and punctured mapping of a quantized value into components and obtain the activate bandpass components with a reduced set of bandpass modulator circuitry.

### BRIEF DESCRIPTION OF THE DRAWINGS

The present disclosure will now be described more fully hereinafter with reference to the accompanying drawings, in which embodiments of the disclosure are shown. However, this disclosure should not be construed as limited to the embodiments set forth herein. Rather, these embodiments are provided so that this disclosure will be thorough and complete, and will fully convey the scope of the disclosure to those skilled in the art. Like numbers refer to like elements throughout.

FIG. 1 illustrates one embodiment of a method of performing quantized amplification with a reduced set of bandpass modulator circuitry in accordance with various aspects as described herein.

FIG. 2A illustrates one embodiment of a system of performing quantized amplification with a reduced set of bandpass modulator circuitry in accordance with various aspects as described herein. FIG. 2B illustrates another embodiment of a system of performing quantized amplification with a reduced set of bandpass modulator circuitry in accordance with various aspects as described herein.

FIG. 3A illustrates one embodiment of a system of performing quantized amplification with a reduced set of bandpass modulator circuitry in accordance with various aspects as described herein. FIG. 3B illustrates another embodiment of a system of performing quantized amplification with a reduced set of bandpass modulator circuitry in accordance with various aspects as described herein.

FIG. 4 illustrates one embodiment of a wireless communication network in accordance with various aspects as described herein.

FIG. 5 illustrates one embodiment of an electronic device in accordance with various aspects as described herein.

### DETAILED DESCRIPTION

For simplicity and illustrative purposes, the present disclosure is described by referring mainly to an exemplary embodiment thereof. In the following description, numerous specific details are set forth in order to provide a thorough understanding of the present disclosure. However, it will be readily apparent to one of ordinary skill in the art that the present disclosure may be practiced without limitation to these specific details.

In coding theory, puncturing is the process of removing some of the parity bits after encoding with an error-correction code. A pre-defined pattern of puncturing is used in an encoder and at the decoder an inverse operation, known as de-puncturing, is implemented. Extending this concept to quantized amplification, the quantization bits can be punctured and mapped into components through a mapping rule that compensates punctured components. The inclusion of compensation terms on the mapping components can have an equivalent effect to the de-puncturing, while the number of DACs and active amplifiers can be reduced and switching devices after the power amplifiers can be also eliminated in the parallel structure.

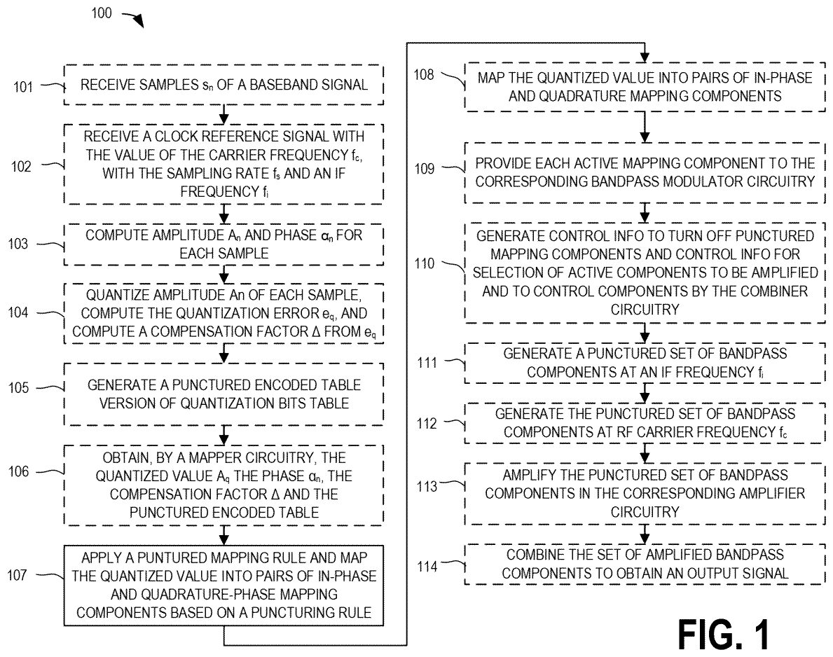

FIG. 1 illustrates one embodiment of a method 100 of performing quantized amplification with a reduced set of bandpass modulator circuitry in accordance with various aspects as described herein. In FIG. 1, the method 100 may start, for instance, at block 101 where it can include receiving samples sₙ of a baseband signal. In one example, the method 100 can include sampling, by a sampling circuitry or a sample and hold (S/H) circuitry, a baseband signal to obtain samples of the input signal. In another example, the method 100 can include receiving in-phase and quadrature-phase components of a baseband signal. At block 102, the method 100 can include receiving a clock reference signal having a carrier frequency f_{c}, a clock reference signal having a sampling rate fₛ, or a clock reference signal having an intermediate frequency fᵢ. At block 103, the method 100 can include determining the amplitude Aₙ and the phase αₙ of each sample. At block 104, the method 100 can include quantizing the amplitude Aₙ of each sample, determining the quantization error e_{q}, or determining a compensation factor Δ from e_{q}. At block 105, the method 105 can include determining a punctured encoding table based on an amplitude quantization bits table that represents quantized values that correspond to a set of quantized bits configured to quantize the amplitude Aₙ of each sample. At block 106, the method 100 can include obtaining, by a mapper circuitry, the quantized amplitude A_{q}, the phase αₙ, the compensation factor Δ, or the punctured encoding table. At block 107, the method 100 includes applying a punctured mapping rule that includes punctured mapping of the quantized amplitude A_{q} into pairs of in-phase and quadrature-phase mapping components based on the punctured mapping rule. At block 108, the method 100 can include mapping, by the mapping circuitry, the quantized amplitude A_{q} into pairs of in-phase and quadrature-phase mapping components. At step 109, the method 100 can include outputting, by the mapper circuitry, each active mapping components to one of a set of bandpass modulator circuitry. At block 110, the method 100 can include determining control information to activate or deactivate punctured mapping components, control information configured to select those punctured mapping components to be amplified to obtain one or more active mapping components, or control information to control a combiner circuitry operable to combine the outputs from a set of power amplifier circuitry. At block 111, the method 100 can include quadrature mixing, by a set of mixer circuitry, the set of active mapping components at an intermediate frequency to obtain a punctured set of bandpass components. At block 112, the method 100 can include upconverting, by a mixer circuitry, the punctured set of bandpass components to an RF carrier frequency f_{c}. At block 113, the method 100 can include amplifying, by a set of power amplifier circuitry, the punctured set of bandpass components to obtain a set of amplified bandpass components. At block 114, the method 100 can include combining, by a combiner circuitry, the set of amplified bandpass components to obtain an output signal.

In another embodiment, the method steps 104 to 109 can be performed in a single method step.

In another embodiment, the punctured encoding table can be stored in a LUT circuitry such that method step 105 is not needed.

In another embodiment, the method steps 101 to 110 can be performed by a single method step using a comparator circuitry and a LUT circuitry having the corresponding amplitude quantization values, the coding puncturing rule, the punctured mapping discrete values, or control information.

In another embodiment, a circuitry, before the quantization circuitry, can be operable to determine the set of phases αₙ or the set of amplitudes Aₙ of successive samples of the input signal.

In another embodiment, the method steps 111 and 112 can include a set of bandpass modulator circuitry to generate the punctured set of bandpass components.

In another embodiment, the method steps 111 and 112 can include a set of bandpass modulator circuitry configured to perform direct up conversation of the active set of mapping components or a set of bandpass modulator circuitry followed by a set of mixer circuitry collectively configured to quadrature modulate the active set of mapping components followed by up-conversion.

In another embodiment, the method steps of quantization, quantization encoding, generating a punctured encoding table, generating of punctured mapping rule, punctured mapping, generating control information and generating bandpass components can be performed in a single method step.

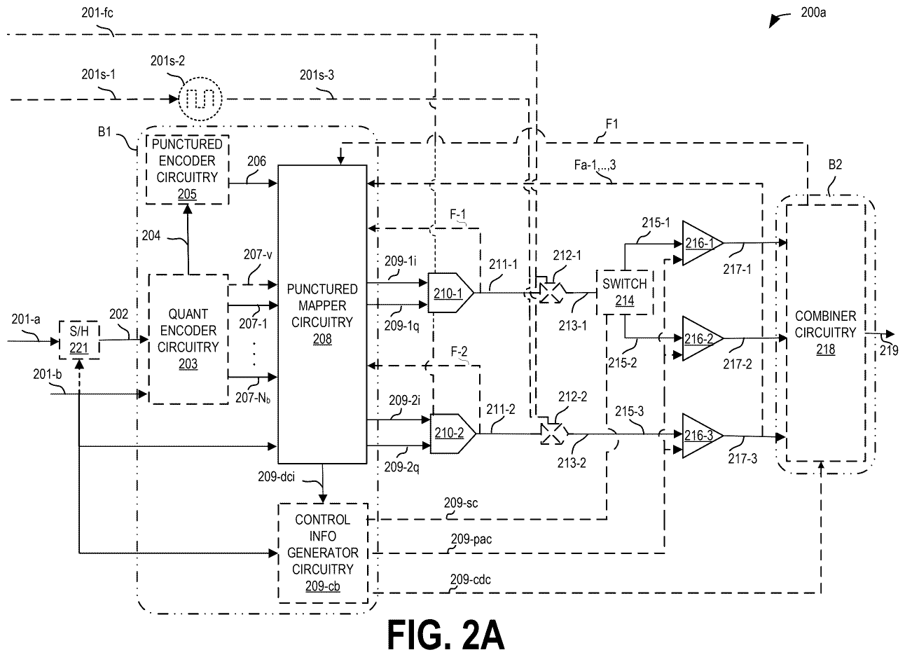

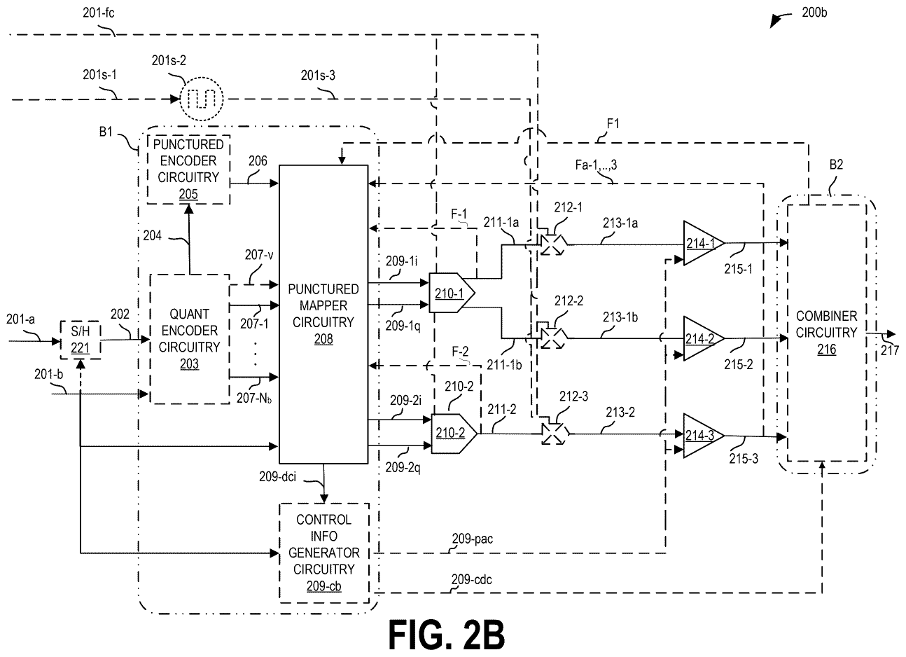

FIG. 2A illustrates one embodiment of a system 200a of performing quantized amplification with a reduced set of bandpass modulator circuitry 210-1, 210-2 in accordance with various aspects as described herein. For an odd number of the set of quantization bits N_{b} that represents the quantized amplitude of each input signal sample and the number of the set of quantization bits N_{b} being at least three (3) bits, the number of the set of N′ pairs of in-phase and quadrature-phase mapping components can be represented by no more than

$${N}^{′} = \frac{{N}_{b} + 1}{2}$$

and the number of bandpass modulator circuitry can be reduced to N′. As illustrated in FIG. 2A, the number of the set of quantization bits N_{b} that represents the quantized amplitude of each input signal is three (3) and the number of bandpass modulator circuitry (e.g., I/Q modulators, I/Q DACs) is reduced to N′ is two (2). Each modulator circuitry can be an I/Q modulator circuitry or I/Q DAC circuitry. The system 200a can be configured to receive an input signal 201-a or time samples sₙ 202 of the input signal 201. The system 200a can also receive a clock reference signal 201-b having the sampling frequency fₛ. Further, the system 200a can receive a reference signal clock 201s-1 having an intermediate frequency fᵢ such as for input to a set of mixer circuitry 212-1, 212-2. In addition, the system 200a can receive a reference signal clock 201-fc having a carrier frequency f_{c}. A skilled artisan will readily recognize that the selection of the clock reference signals can be made according to the bandwidth of the input signal, the desired frequency of the output signal, a frequency shift to up-convert bandpass components, or the like.

In another embodiment, the input signal 201-a can include the samples s_{In} and s_{Qn} representing the in-phase and quadrature-phase components of a baseband signal.

In another embodiment, the input signal 201-a can include a baseband signal s(t), which can be sampled by sample and hold circuitry 221 to obtain the time samples sₙ=s(tₙ).

In FIG. 2A, the clock signal 201-b can be a clock reference signal having a sampling frequency and can be input to the sampling circuitry 221, the quantization encoding circuitry 203, the punctured encoder circuitry 205, a punctured mapper circuitry 208, a control information generator circuitry 209-cb, the set of modulator circuitry 210-1, 210-2, the active set of amplifier circuitry 216-1, 216-2, 216-3 selected among the set of amplifier circuitry 216-1, 216-2, 216-3, or a combiner circuitry 218.

In the current embodiment, the quantizer encoder circuitry 203 can be operable to receive the samples sₙ of the input signal s(t), determine the amplitude

$${A}_{n} = \sqrt{{s}_{I , n}^{2} + {s}_{Q , n}^{2}} ,$$

and the phase αₙ=ATAN(s_{Q,n}/s_{I,n}) of each samples sₙ. The quantizer encoder circuitry 203 can apply a quantization encoding table having N_{b} quantization bits for each quantized amplitude A_{qn} value, a table having a finite set of quantization amplitude values, a table having sets of discrete amplitude values of quantization components aᵢ={a₁, a₂, . . . , a_{Nb}} in which the quantized amplitude A_{qn} can be decomposed, or the set of quantized amplitude values. The quantizer encoder circuitry 203 can be operable to quantize the amplitude Aₙ of each sample sₙ, determine the quantized amplitude A_{qn}=Aₙ+e_{q} or the set of quantization amplitude bits 207-{1, . . . , N_{b}}, or compute a compensation factor Δ belonging to a finite discrete alphabet based on the quantization error e_{q}. The quantizer encoder circuitry 203 can be operable to output, to the punctured mapper circuitry 208, a signal 207-v that includes the amplitude Aₙ, the phase αₙ or the compensation factor Δ of the input signal sample sₙ, and output the set of quantization amplitude bits 207-{1, . . . , N_{b}} that represents the quantized amplitude Aₙ of the input signal sample. Further, the quantizer encoder circuitry 203 can be operable to output, to a punctured encoder circuitry 205, a quantization encoding table 204 such as represented by:

Quantization Encoding Table

| Bit 3 | Bit 2 | Bit 1 |
|---|---|---|
| 0 | 0 | 0 |
| 0 | 0 | 1 |
| 0 | 1 | 0 |
| 0 | 1 | 1 |
| 1 | 0 | 0 |
| 1 | 0 | 1 |
| 1 | 1 | 0 |
| 1 | 1 | 1 |

In FIG. 2A, the punctured encoder circuitry 205 can be operable to generate a punctured encoding table 206 based on the quantization encoding table 204. In one example, the punctured encoding table 206 and the equivalent mapping with component puncturing can be represented by the table below and can enable a system to have two (2) DAC circuitry and a set of three (3) power amplifier circuitry.

| Equivalent Bit Coding | | | | | |
|---|---|---|---|---|---|
| with Bit Puncturing | | | Equivalent Mapping with Component Puncturing | | |
| Bit 3 | Bit 2 | Bit 1 | C₃ | C₂ | C₁ |
| 0 | 0 | 0 | 0 | 0 | 1 |
| 0 | 0 | 1 | 0 | 0 | a₁ + Δ |
| 0 | 1 | 0 | 0 | a₂ + Δ | 0 |
| 0 | 1 | 1 | 0 | ${a}_{2} + \frac{{a}_{2}}{{a}_{2} + {a}_{1}} Δ$ | ${a}_{1} + \frac{{a}_{1}}{{a}_{2} + {a}_{1}} Δ$ |
| 1 | 0 | 0 | a₃ + Δ | 0 | 0 |
| 1 | 0 | 1 | ${a}_{3} + \frac{{a}_{3}}{{a}_{3} + {a}_{1}} Δ$ | 0 | ${a}_{1} + \frac{{a}_{1}}{{a}_{3} + {a}_{1}} Δ$ |
| 1 | 1 | 0 | ${a}_{3} + \frac{{a}_{3}}{{a}_{3} + {a}_{2}} Δ$ | ${a}_{2} + \frac{{a}_{2}}{{a}_{3} + {a}_{2}} Δ$ | 0 |
| 1 | 1 | X | ${a}_{3} + \frac{{a}_{3}}{{a}_{3} + {a}_{2}} ( Δ + {a}_{1} )$ | ${a}_{2} + \frac{{a}_{2}}{{a}_{3} + {a}_{2}} ( Δ + {a}_{1} )$ | X |

In the table above, ‘X’ denotes the punctured bits, Δ represents the quantized quantization noise and aᵢ, i=1, 2, 3 represents the amplitudes of mapping components. C₁ component amplitudes can belong to a finite alphabet with possible values of

$$\{ 0 , Δ , {a}_{1} + Δ , {a}_{1} + \frac{{a}_{1}}{{a}_{2} + {a}_{1}} Δ , {a}_{1} + \frac{{a}_{1}}{{a}_{3} + {a}_{1}} Δ \} .$$

C₂ component amplitudes can belong to a finite alphabet with possible values of

$$\{ 0 , {a}_{2} + Δ , {a}_{2} + \frac{{a}_{2}}{{a}_{2} + {a}_{1}} Δ , {a}_{2} + \frac{{a}_{2}}{{a}_{3} + {a}_{2}} Δ , {a}_{2} + \frac{{a}_{2}}{{a}_{3} + {a}_{2}} ( Δ + {a}_{1} ) \} .$$

C₃ component amplitudes can belong to a finite alphabet with possible values of

$$\{ 0 , {a}_{3} + Δ , {a}_{3} + \frac{{a}_{3}}{{a}_{3} + {a}_{1}} Δ , {a}_{3} + \frac{{a}_{3}}{{a}_{3} + {a}_{2}} Δ , {a}_{3} + \frac{{a}_{3}}{{a}_{3} + {a}_{2}} ( Δ + {a}_{1} ) \} ,$$

where Δ is a discrete correction factor with values belonging to a discrete and finite alphabet. Amplitudes a₁, a₂, a₃ and a₄ can be defined to enable a preferable power relation between components to increase the combination efficiency at the combiner circuitry and can assume different values belonging to a discrete and limited set of possible values for each combiner type.

In another example, the punctured encoding table 206 and the equivalent mapping with component puncturing can be represented by the table below and can enable a system to have two (2) DAC circuitry and a set of three (3) power amplifier circuitry.

| Equivalent Bit Coding | | | | | |
|---|---|---|---|---|---|
| with Bit Puncturing | | | Equivalent Mapping with Component Puncturing | | |
| Bit 3 | Bit 2 | Bit 1 | C₃ | C₂ | C₁ |
| 0 | 0 | 0 | 0 | 0 | Δ |
| 0 | 0 | 1 | 0 | 0 | a₁ + Δ |
| 0 | 1 | 0 | 0 | a₂ + Δ | 0 |
| 0 | 1 | 1 | 0 | ${a}_{2} + \frac{{a}_{2}}{{a}_{2} + {a}_{1}} Δ$ | ${a}_{1} + \frac{{a}_{1}}{{a}_{2} + {a}_{1}} Δ$ |
| 1 | 0 | 0 | a₃ + Δ | 0 | 0 |
| 1 | 0 | X | a₃ + Δ + a₁ | 0 | X |
| 1 | 1 | 0 | ${a}_{3} + \frac{{a}_{3}}{{a}_{3} + {a}_{2}} Δ$ | ${a}_{2} + \frac{{a}_{2}}{{a}_{3} + {a}_{2}} Δ$ | 0 |
| 1 | 1 | X | ${a}_{3} + \frac{{a}_{3}}{{a}_{3} + {a}_{2}} ( Δ + {a}_{1} )$ | ${a}_{2} + \frac{{a}_{2}}{{a}_{3} + {a}_{2}} ( Δ + {a}_{1} )$ | X |

where ‘X’ denotes the punctured bits, Δ represents the quantized quantization noise and aᵢ, i=1, 2, 3 represent the amplitudes of the mapping components. C₁ component amplitudes can belong to a finite alphabet with possible values of

$$\{ 0 , Δ , {a}_{1} + Δ , {a}_{1} + \frac{{a}_{1}}{{a}_{2} + {a}_{1}} Δ \} .$$

C₂ component amplitudes can belong to a finite alphabet with possible values of

$$\{ 0 , {a}_{2} + Δ , {a}_{2} + \frac{{a}_{2}}{{a}_{2} + {a}_{1}} Δ , {a}_{2} + \frac{{a}_{2}}{{a}_{3} + {a}_{2}} Δ , {a}_{2} + \frac{{a}_{2}}{{a}_{3} + {a}_{2}} ( Δ + {a}_{1} ) \} .$$

C₃ component amplitudes can belong to a finite alphabet with possible values of

$$\{ 0 , {a}_{3} + Δ , {a}_{3} + Δ + {a}_{1} , {a}_{3} + \frac{{a}_{3}}{{a}_{3} + {a}_{2}} Δ , {a}_{3} + \frac{{a}_{3}}{{a}_{3} + {a}_{2}} ( Δ + {a}_{1} ) \} ,$$

where Δ is a discrete correction factor with values belonging to a discrete and finite alphabet. Amplitudes a₁, a₂ and a₃ can be defined to enable a preferable relation between components to increase the combination efficiency at the combiner circuitry and can assume different values always belonging to a discrete and limited set of possible values for each combiner type.

Furthermore, the punctured encoder circuitry 205 can be operable to output, to the punctured mapper circuitry 208, the punctured encoding table 206. The punctured mapper circuitry 208 can be operable to receive the quantization bits 207-{1, . . . , N_{b}}, the signal 207-v that includes the amplitude Aₙ, the phase αₙ or the compensation factor Δ of the input signal sample sₙ, or the punctured encoding table 206 and generate a set of N′≤N_{b} active pairs of in-phase and quadrature-phase mapping components based on a mapping table, which can be stored in a LUT circuitry that can include the mapping component values based on a certain puncturing rule, the quantization bit combinations, the sets of discrete amplitudes aᵢ, or the set of quantized amplitude values. The punctured mapper circuitry 208 can be operable to select the mapping values of the corresponding mapping components from a punctured mapping table based on the quantization amplitude bits and the punctured encoding table 206. In another example, the punctured mapping table can be represented by:

Mapping Components with Puncturing

| C₃ | C₂ | C₁ |
|---|---|---|
| ${C}_{3}^{( 1 )}$ | ${C}_{2}^{( 1 )}$ | ${C}_{1}^{( 1 )}$ |
| ${C}_{3}^{( 2 )}$ | ${C}_{2}^{( 2 )}$ | ${C}_{1}^{( 2 )}$ |
| ${C}_{3}^{( 3 )}$ | ${C}_{2}^{( 3 )}$ | ${C}_{1}^{( 3 )}$ |
| ${C}_{3}^{( 4 )}$ | ${C}_{2}^{( 4 )}$ | ${C}_{1}^{( 4 )}$ |
| ${C}_{3}^{( 5 )}$ | ${C}_{2}^{( 5 )}$ | ${C}_{1}^{( 5 )}$ |
| ${C}_{3}^{( 6 )}$ | ${C}_{2}^{( 6 )}$ | X |
| ${C}_{3}^{( 7 )}$ | ${C}_{2}^{( 7 )}$ | ${C}_{1}^{( 6 )}$ |
| ${C}_{3}^{( 8 )}$ | ${C}_{2}^{( 8 )}$ | X |

with the coefficients

$${C}_{k}^{( i )} ,$$

k=1, . . . , N_{b}, configured to map the quantized amplitude value into N′≤N_{b} pairs of in-phase s_{I,n} and quadrature-phase s_{Q,n} mapping components 209-1ᵢ, 209-2ᵢ and 209-1_{q}, 209-2_{q}, given by Cₖ cos(αₙ) and Cₖ sin(αn) with k=1, . . . , N_{b}. C₁ mapping coefficient can assume values from a set of amplitudes

$${C}_{1}^{( i )} ,$$

i=1, . . . , 6 that belong to a discrete alphabet A₁ with possible values of

$$\{ 0 , Δ , {a}_{1} + Δ , {a}_{1} + \frac{{a}_{1}}{{a}_{2} + {a}_{1}} Δ \} ,$$

where Δ is the discrete compensation factor with values belonging to a finite alphabet. C₂ mapping coefficient can assume values from a set of amplitudes

$${C}_{2}^{( i )} ,$$

i=1, . . . , 8 belonging to a discrete alphabet A₂ with possible values of

$$\{ 0 , {a}_{2} + Δ , {a}_{2} + \frac{{a}_{2}}{{a}_{2} + {a}_{1}} Δ , {a}_{2} + \frac{{a}_{2}}{{a}_{3} + {a}_{2}} Δ , {a}_{2} + \frac{{a}_{2}}{{a}_{3} + {a}_{2}} ( Δ + {a}_{1} ) \} .$$

C₃ mapping coefficient can assume values from a set of amplitudes

$${C}_{3}^{( i )} ,$$

i=1, . . . , 8 belonging to a discrete alphabet A₃ with possible values of

$$\{ 0 , {a}_{3} + Δ , {a}_{3} + Δ + {a}_{1} , {a}_{3} + \frac{{a}_{3}}{{a}_{3} + {a}_{2}} Δ , {a}_{3} + \frac{{a}_{3}}{{a}_{3} + {a}_{2}} ( Δ + {a}_{1} ) \} .$$

Amplitudes a₁, a₂ and a₃ can be defined to increase energy efficiency and can assume different values belonging to a discrete and limited set of possible values.

In another embodiment, the quantizer encoder circuitry 203, the punctured encoder circuitry 205 or the punctured mapper circuitry 208 can be configured to include LUT circuitry having the punctured mapping table, the punctured coding table, the quantization encoding table, the quantization values table, the quantization amplitude components table, or the like.

In another embodiment, a single LUT circuitry can include the punctured mapping table, punctured coding table, quantization encoding table, quantization values table, quantization amplitude components table, or the like.

In FIG. 2A, the punctured mapper circuitry 208 can output, to a set of N′ bandpass modulator circuitry 210-1, 210-2, the active set of N′ pairs of in-phase and quadrature-phase mapping components 209-1i, 209-2i and 209-1q, 209-2q. The set of N′ bandpass modulator circuitry 210-1, 210-2 can be operable to quadrature modulate the active set of N′ pairs of in-phase and quadrature-phase mapping components 209-1i, 209-2i and 209-1q, 209-2q to obtain a punctured set of N′ bandpass components 211-1, 211-2.

In another embodiment, the set of bandpass modulator circuitry 210-1, 210-2 can be operable to further upconvert the punctured set of bandpass components 211-1, 211-2 to a carrier frequency f_{c}, with the upconverted signals 211-1, 211-2 having the same frequency of signals 213-1, 213-2 without the up-conversion performed by the set of mixer circuitry 212-1, 212-2.

In FIG. 2A, the number of active mapping components 209-1i, 209-2i and 209-19, 209-2q is two (2) and the number of the set of bandpass modulator circuitry 210-1, 210-2 is also two (2). Due to puncturing, the amplitude of mapping signals 209-i1, 209-q1 can assume values of the C₁ or C₃ mapping coefficient, and the bandpass modulator circuitry 210-1 can generate bandpass components 211-1 associated with the respective C₁ or C₃ mapping coefficient. The punctured mapper circuitry 208 can also output, to the control information generator circuitry 209-cb, a signal 209-dci having information related to the mapping rule applied to each quantized amplitude value. The control information generator circuitry 209-cb can be operable to generate control information to active or deactivate the set of mixer circuitry 212-1, 212-2 or the set of power amplifier circuitry 216-1 to 216-3 that corresponds to the active set of mapping components 209-1i, 209-2i and 209-1q, 209-2q.

In another embodiment, the punctured mapper circuitry 208 can be operable to output, to the set of active bandpass modulator circuitry 210-1, 210-2, the phase αₙ of each sample to control the initial phase of the sinusoidal signals generated by the set of bandpass modulators for each sampling interval.

In another embodiment, the active set of bandpass modulator circuitry 210-1, 210-2 can be operable to generate the punctured set of bandpass components 213-1, 213-2 at the intermediate frequency fᵢ. Further, a set of mixer circuitry 212-1 and/or 212-2 can be operable to up-convert the punctured set of N′ bandpass components to the carrier frequency f_{c}.

In FIG. 2A, the bandpass component 213-1 can be the bandpass component associated with the C₁ or C₃ mapping components and can be input to a switch circuitry 214 operable to select one of a set of amplification branches 215-1, 215-2 that corresponds to the active mapping coefficient. The switch circuitry 214 can be controlled by an input signal 209-sc configured to select one of those amplification branches 215-1, 215-2. In addition, the set of power amplifier circuitry 216-1, 216-2, 216-3 can be operable to amplify the punctured set of bandpass components 215-1 or 215-2, 215-3 to obtain the active set of amplified signals 217-1 or 217-2, 217-3. The combiner circuitry 218 can be operable to combine the active set of amplified signals 217-1 or 217-2, 217-3 to obtain an output signal 219 that corresponds to the active set of amplified signals 217-1 or 217-2, 217-3 and the punctured set of bandpass components 215-1 or 215-2, 215-3.

In another embodiment, the control information generator circuitry 209-cb can be operable to determine control information 209-pac for power amplifier activation and deactivation and control information 209-cdc to control power combiner 218 of circuitry B2. In addition, oscillator 201s-02 can be configured to receive signal 201s-1 associated with a reference frequency.

In another embodiment, the system 200a,b can receive signal 201-f_{c} associated with a reference frequency of the carrier frequency f_{c}.

In another embodiment, the system 200a,b can receive signal 201s-1 associated with a reference frequency of the intermediate frequency fᵢ.

In another embodiment, the system 200a can receive signal 201s-1 associated with a reference frequency that corresponds to the up-conversion from the intermediate frequency fᵢ to the RF frequency f_{c}. For instance, the oscillator 201s-2 signal can be operable to receive the signal 201s-1 associated with the intermediate frequency fᵢ and generate a reference sinusoidal signal 201s-3 for input to the set of mixer circuitry 212-1, 212-2 operable to up-convert signals 211-1, 211-2 to the intermediate frequency fᵢ.

In another embodiment, the set of bandpass modulator circuitry 210-1, 210-2 can be operable to output, to the punctured mapper circuitry 208, feedback information F-1, F-2 to enable the punctured mapper circuitry 208 to determine phase or time control information for the set of bandpass modulator circuitry 210-1, 210-2 so as to time or phase synchronize the punctured set of bandpass components at the outputs of the set of mixer output circuitry or the set of power amplifier circuitry.

In another embodiment, the system 200a can be configured to feedback, to the punctured mapper circuitry 208, the set of amplified bandpass components 217-1, 217-2, 217-3 to enable the punctured mapper circuitry 208 to determine phase or time control information for input to the set of bandpass modulator circuitry 210-1, 210-2 so as to time or phase synchronize the active set of amplified bandpass components.

In another embodiment, the set of mixer circuitry 212-1, 212-2 can be configured to feedback, to the punctured mapper circuitry 208, the signals 213-1, 213-2. The punctured mapper circuitry 208 can be operable to determine time or phase control information for input to the active set of the bandpass modulators 210-1, 210-2 based on the signals 213-1, 213-2 so as to time or phase synchronize the punctured set of bandpass components 215-1 or 215-2, 215-3 and the active set of amplified bandpass components 217-1 or 217-2, 217-3.

In another embodiment, the system 200a can be configured to receive the clock reference signal 2012-01 having the intermediate frequency fᵢ, to enable the set of bandpass modulator circuitry 210-1, 210-2. Further, the set of mixer circuitry 212-1, 212-2 can be configured to receive the input clock reference signal 201-f_{c} having the carrier frequency to enable up-conversion of the punctured set of bandpass components 211-1, 211-2.

In another embodiment, circuitry B1 can include the punctured mapper circuitry 208, the quantizer encoder circuitry 203, or the control information generator circuitry 209-cb can be implemented in a single circuitry block by hardware, software or firmware, including digital or analog techniques and with or without a microprocessor, a field programmable gate array (FPGA) or a digital signal processor (DSP).

FIG. 2B illustrates another embodiment of a system 200b of performing quantized amplification with a reduced set of bandpass modulator circuitry 210-1, 210-2 in accordance with various aspects as described herein. In FIG. 2B, the bandpass modulator circuitry 210-1 can be configured as an I/Q modulator circuitry or an I/Q DAC circuitry, with each having two outputs with one output being active during each sample interval. The punctured mapper circuitry 208 can be operable to generate the set of N′ pairs of in-phase and quadrature-phase mapping components 209-1i, 209-2i and 209-1q, 209-2q for output to the set of bandpass modulator circuitry 210-1, 210-2 operable to generate the punctured set of bandpass components 211-1a or 211-1b, 211-2. In FIG. 2B, the number of active mapping components is two (2) and the number of the set of bandpass modulator circuitry 210-1, 210-2 is also two (2), with one of the set of bandpass modulator circuitry 210-1, 210-2 having two outputs with only one of these outputs to be active during a sample period. Due to puncturing, the amplitudes of the mapping signals 209-i1 and 209-q1 can assume values of the C₁ and C₃ mapping coefficients. Further, the bandpass modulator 210-1 is configured to output bandpass component 211-1a or 211-1b that corresponds to the respective C₁ or C₃ mapping coefficient. The punctured mapper circuitry 208 can be configured to determine the control information 209-dci associated with the mapping rule applied to each quantized value so that the control information generator circuitry 209-cb can be enabled to determine control information to activate or deactivate the set of mixer circuitry 212-1 or 212-2, 212-3, activate or deactivate the set of power amplifier circuitry 214-1 or 214-2, 214-3 corresponding to the active set of mapping components.

In another embodiment, the punctured mapper circuitry 208 can be operable to determine the phase n of each sample and output that phase αₙ to the active set of bandpass modulator circuitry 210-1, 210-2 operable to control the initial phase of the sinusoidal signals generated by the set of bandpass modulator circuitry 210-1, 210-2 for each sampling interval.

In another embodiment, the set of bandpass modulator circuitry 210-1, 210-2 can be operable to generate the punctured set of bandpass components 211-1a or 211-1b, 211-2 at the intermediate frequency fᵢ. Further, the active set of mixer circuitry 212-1 or 212-2, 212-3 can be operable to up-convert the punctured set of bandpass components 212-1 or 212-2, 212-3 to the carrier frequency f_{c}.

In FIG. 2B, the active set of power amplifiers 214-1 or 214-2, 214-3 can be operable to amplify the active set of signals 213-1a or 213-1b, 213-2 to obtain an active set of amplified signals 215-1 or 215-2, 215-3. Further, the combiner circuitry 216 can be operable to combine the active set of amplified signals 215-1 or 215-2, 215-3 to obtain an output signal 217.

In another embodiment, the control information generator 209-cb can be operable to determine control information 209-pac configured for the activation or deactivation of the set of power amplifier circuitry 214-1, 214-2, 214-3 or determine control information 209-cdc configured to control which of the set of amplified signals 215-1 or 215-2, 215-3 are combined by the combiner circuitry 216.

In another embodiment, the set of mixer circuitry 212-1, 212-2, 212-3 can be operable to feedback, to the punctured mapper circuitry 208, feedback information. The punctured mapper circuitry 208 can be operable to determine phase or time control information for the set of bandpass modulator circuitry 210-1, 210-2 to enable time or phase synchronization of the punctured set of bandpass components 213-1a or 213-1b, 213-2 and the active set of amplified bandpass components 215-1 or 215-2, 215-3.

In another embodiment, the punctured mapper circuitry 208 can be configured to receive, from the set of bandpass modulator circuitry 210-1, 210-2, feedback information Fo₁, Fo₂. Further, the punctured mapper circuitry 208 can be operable to determine time or phase control information for the set of bandpass modulator circuitry 210-1, 210-2 to enable time or phase synchronization of the punctured set of bandpass components 211-1a, 211-1b, 211-2 at the active set of mixer circuitry 212-1, 212-2, 212-3 or the active set of signals 213-1a, 213-1b, 213-2 at the active set of power amplifier circuitry 214-1, 214-2, 214-3.

In another embodiment, the punctured mapper circuitry 208 can be operable to receive feedback signals Fa-1, Fa-2, Fa-3 associated with the amplified bandpass components 215-1, 215-2, 215-3. Further, the punctured mapper circuitry 208 can be operable to determine time or phase control information for the active set of bandpass modulator circuitry 210-1, 210-2 to enable time or phase synchronization of the active set of amplified bandpass components 215-1, 215-2, 215-3.

In another embodiment, the system 200b can be configured to receive a clock reference signal 201s-1 having an intermediate frequency fᵢ, for input to the set of bandpass modulator circuitry 210-1, 210-2 (e.g., I/Q modulators, I/Q DACs).

In another embodiment, the system 200b can be configured to receive input signal 201-f_{c} having a carrier frequency for input to the set of mixer circuitry 212-1, 212-2, 212-3 operable to up-convert the punctured set of bandpass components 211-1a, 211-1b, 211-2.

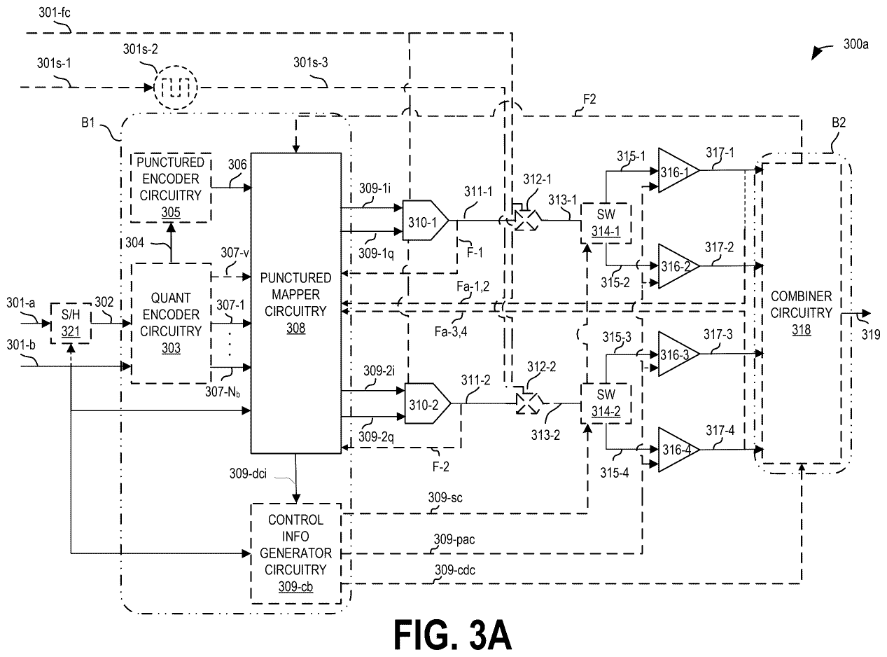

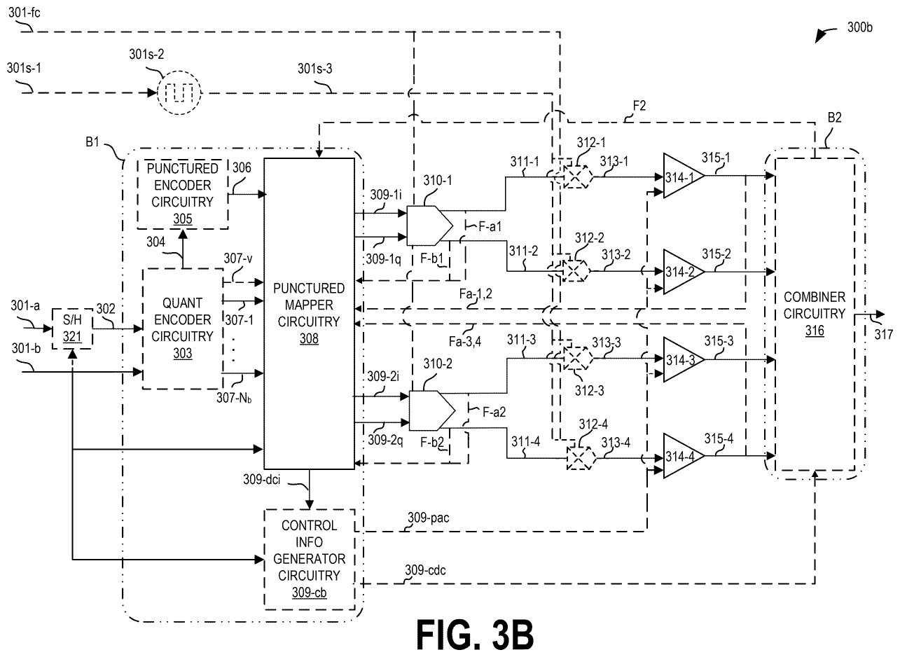

FIG. 3A illustrates one embodiment of a system 300a of performing quantized amplification with a reduced set of bandpass modulator circuitry 310-1, 310-2 in accordance with various aspects as described herein. For an even number of the set of quantization bits N_{b} that represent the quantized amplitude of each input signal sample and the number of the set of quantization bits N_{b} being at least four (4) bits, the number of the set of N′ pairs of in-phase and quadrature-phase mapping components 309-1i, 309-2i and 309-1q, 309-2q can be no more than

$${N}^{′} = \frac{{N}_{b}}{2}$$

and the number of bandpass modulator circuitry 310-1, 310-2 can be reduced to N′. As illustrated in FIG. 3A, the number of the set of quantization bits Np that represent the quantized amplitude of each input signal sample is four (4) bits and the number of the set of bandpass modulator circuitry 310-1, 310-2 (e.g., I/Q modulators, I/Q DACs) is reduced to N′ equal to two (2). The system 300a can receive an input signal 301-a or time samples sₙ 302 of a baseband signal. In one example, the input signal 301-a can include the samples s_{In} and s_{Qn} of the in-phase and quadrature-phase components of a baseband signal. In another example, the input signal 301-a is a baseband signal s(t) which is sampled by sample and hold circuitry 321 to obtain the time samples sₙ=s(tₙ).

In FIG. 3A, the system 300a can also receive a clock reference signal 301-b having the sampling frequency fₛ and a clock reference signal 301-f_{c} with the carrier frequency f_{c}. The system can also receive the reference signal clock 301s-1 having an Intermediate frequency fᵢ for input to a set of mixer circuitry 312-1, 312-2. A skilled artisan will readily recognize that selection of a clock reference signal can be made according to the bandwidth of the input signal, the desired frequency of the output signal, the frequency for IF or RF up-conversion, or the like. The clock signal 301-b can be a clock reference signal having the sampling frequency for input to sampling circuitry 321, quantization encoding circuitry 303, punctured encoder circuitry 305, punctured mapper circuitry 308, control information generator circuitry 309-cb, the set of bandpass modulator circuitry 310-1, 310-2, selection among the set of power amplifiers 316-1, 316-2, 316-3, 316-4, combiner circuitry 318, or the like.

In the current embodiment, the quantizer encoder circuitry 303 can be operable to receive the samples sₙ of s(t), compute amplitude

$${A}_{n} = \sqrt{{s}_{I , n}^{2} + {s}_{Q , n}^{2}} , {α}_{n} = A TAN ( {s}_{Q , n} / {s}_{I , n} ) .$$

The quantizer encoder circuitry 303 can be configured to include a quantization encoding table representing N_{b} quantization bits for each quantized amplitude value, a table with the finite set of quantization values, a table with the sets of discrete amplitudes of quantization components aᵢ={a₁, a₂, . . . , a_{Nb}} in which the quantized value can be decomposed, the set of quantized amplitude values, or the like. The quantizer encoder circuitry 303 can be operable to quantize amplitude Aₙ of each sample, generate the quantized value A_{qn}=Aₙ+e_{q}, generate the set of quantization amplitude bits 307-1 to 307-N_{b}, compute a compensation factor Δ belonging to a finite discrete alphabet based on the quantization amplitude error e_{q}. The quantizer encoder circuitry 303 can be operable to output, to the punctured mapper circuitry 308, the quantization amplitude bits 307-1 to 307-N_{b}, the amplitude Aₙ, the phase αₙ or the compensation factor Δ via signal 307-v, or the like. The quantizer encoder circuitry can be configured to output, to the punctured encoder circuitry 305, a binary mapping quantization encoding table 304 configured to enable the generation of a punctured encoding table 306. In one example, the binary mapping quantization encoding table 304 can be represented by:

Binary Quantization
Mapping Table

| Bit 4 | Bit 3 | Bit 2 | Bit 1 |
|---|---|---|---|
| 0 | 0 | 0 | 0 |
| 0 | 0 | 0 | 1 |
| 0 | 0 | 1 | 0 |
| 0 | 0 | 1 | 1 |
| 0 | 1 | 0 | 0 |
| 0 | 1 | 0 | 1 |
| 0 | 1 | 1 | 0 |
| 0 | 1 | 1 | 1 |
| 1 | 0 | 0 | 0 |
| 1 | 0 | 0 | 1 |
| 1 | 0 | 1 | 0 |
| 1 | 0 | 1 | 1 |
| 1 | 1 | 0 | 0 |
| 1 | 1 | 0 | 1 |
| 1 | 1 | 1 | 0 |
| 1 | 1 | 1 | 1 |

In one example, the punctured encoding table 306 can be represented by:

Equivalent Bit Coding with Bit Puncturing

| Bit 4 | Bit 3 | Bit 2 | Bit 1 |
|---|---|---|---|
| 0 | 0 | 0 | 0 |
| 0 | 0 | 0 | 1 |
| 0 | 0 | 1 | 0 |
| 0 | 0 | 1 | 1 |
| 0 | 1 | 0 | 0 |
| 0 | 1 | 0 | X |
| 0 | 1 | 1 | 0 |
| 0 | 1 | 1 | X |
| 1 | 0 | 0 | 0 |
| 1 | 0 | 0 | X |
| 1 | 0 | X | 0 |
| 1 | 0 | X | X |
| 1 | 1 | 0 | 0 |
| 1 | 1 | 0 | X |
| 1 | 1 | X | 0 |
| 1 | 1 | X | X |

where ‘X’ denotes a punctured bit. The punctured encoder circuitry 305 can be operable to output, to the punctured mapper circuitry 308, a representation 306 of this punctured encoding table.

In another example, the punctured encoding table 306 and the equivalent mapping with component puncturing can be represented by the table below and can enable a system to have two (2) DAC circuitry and a set of four (4) power amplifier circuitry.

| Equivalent Bit Coding with | | | | | | | |
|---|---|---|---|---|---|---|---|
| Bit Puncturing | | | | Equivalent Mapping with Component Puncturing | | | |
| Bit 4 | Bit 3 | Bit 2 | Bit 1 | C₄ | C₃ | C₂ | C₁ |
| 0 | 0 | 0 | 0 | 0 | 0 | 0 | Δ |
| 0 | 0 | 0 | 1 | 0 | 0 | 0 | a₁ + Δ |
| 0 | 0 | 1 | 0 | 0 | 0 | a₂ + Δ | 0 |
| 0 | 0 | 1 | 1 | 0 | 0 | ${a}_{2} + \frac{{a}_{2}}{{a}_{2} + {a}_{1}} Δ$ | ${a}_{1} + \frac{{a}_{1}}{{a}_{2} + {a}_{1}} Δ$ |
| 0 | 1 | 0 | 0 | 0 | a₃ + Δ | 0 | 0 |
| 0 | 1 | 0 | X | 0 | a₃ + Δ + a₁ | 0 | X |
| 0 | 1 | 1 | 0 | 0 | ${a}_{3} + \frac{{a}_{3}}{{a}_{3} + {a}_{2}} Δ$ | ${a}_{2} + \frac{{a}_{2}}{{a}_{3} + {a}_{2}} Δ$ | 0 |
| 0 | 1 | 1 | X | 0 | ${a}_{3} + \frac{{a}_{3}}{{a}_{3} + {a}_{2}} ( Δ + {a}_{1} )$ | ${a}_{2} + \frac{{a}_{2}}{{a}_{3} + {a}_{2}} ( Δ + {a}_{1} )$ | X |
| 1 | 0 | 0 | 0 | a₄ + Δ | 0 | 0 | 0 |
| 1 | 0 | 0 | X | a₄ + Δ + a₁ | 0 | 0 | X |
| 1 | 0 | X | 0 | a₄ + Δ + a₂ | 0 | X | 0 |
| 1 | 0 | X | X | a₄ + Δ + a₂ + a₁ | 0 | X | X |
| 1 | 1 | 0 | 0 | ${a}_{4} + \frac{{a}_{4}}{{a}_{4} + {a}_{3}} Δ$ | ${a}_{3} + \frac{{a}_{3}}{{a}_{4} + {a}_{3}} Δ$ | 0 | 0 |
| 1 | 1 | 0 | X | ${a}_{4} + \frac{{a}_{4}}{{a}_{4} + {a}_{3}} ( Δ + {a}_{1} )$ | ${a}_{3} + \frac{{a}_{3}}{{a}_{4} + {a}_{3}} ( Δ + {a}_{1} )$ | 0 | X |
| 1 | 1 | X | 0 | ${a}_{4} + \frac{{a}_{4}}{{a}_{4} + {a}_{3}} ( Δ + {a}_{2} )$ | ${a}_{3} + \frac{{a}_{3}}{{a}_{4} + {a}_{3}} ( Δ + {a}_{2} )$ | X | 0 |
| 1 | 1 | X | X | ${a}_{4} + \frac{{a}_{4}}{{a}_{4} + {a}_{3}} ( Δ + {a}_{1} + {a}_{2} )$ | ${a}_{3} + \frac{{a}_{3}}{{a}_{4} + {a}_{3}} ( Δ + {a}_{1} + {a}_{2} )$ | X | X |

C₁ component amplitudes can belong to a finite alphabet with possible values of

$$\{ 0 , Δ , {a}_{1} + Δ , {a}_{1} + \frac{{a}_{1}}{{a}_{2} + {a}_{1}} Δ \} .$$

C₂ component amplitudes can belong to a finite alphabet with possible values of

$$\{ 0 , {a}_{2} + Δ , {a}_{2} + \frac{{a}_{2}}{{a}_{2} + {a}_{1}} Δ , {a}_{2} + \frac{{a}_{2}}{{a}_{3} + {a}_{2}} Δ , {a}_{2} + \frac{{a}_{2}}{{a}_{3} + {a}_{2}} ( Δ + {a}_{1} ) \} .$$

C₃ component amplitudes can belong to a finite alphabet with possible values of

$$\{ 0 , {a}_{3} + Δ , {a}_{3} + Δ + {a}_{1} , {a}_{3} + \frac{{a}_{3}}{{a}_{4} + {a}_{3}} Δ , {a}_{3} + \frac{{a}_{3}}{{a}_{4} + {a}_{3}} ( Δ + {a}_{1} ) , {a}_{3} + \frac{{a}_{3}}{{a}_{4} + {a}_{3}} Δ , {a}_{3} + \frac{{a}_{3}}{{a}_{4} + {a}_{3}} ( Δ + {a}_{1} ) , {a}_{3} + \frac{{a}_{3}}{{a}_{4} + {a}_{3}} ( Δ + {a}_{2} ) , \frac{{a}_{3}}{{a}_{4} + {a}_{3}} ( Δ + {a}_{1} + {a}_{2} ) \} ,$$

where Δ is a discrete correction factor with values belonging to a discrete and finite alphabet. C₄ component amplitudes belong to a finite alphabet with possible values of

$$\{ 0 , {a}_{4} + Δ , {a}_{4} + Δ + {a}_{1} , {a}_{4} + Δ + {a}_{2} , {a}_{4} + Δ + {a}_{2} + {a}_{1} , {a}_{4} + \frac{{a}_{4}}{{a}_{4} + {a}_{3}} Δ , {a}_{4} + \frac{{a}_{4}}{{a}_{4} + {a}_{3}} ( Δ + {a}_{1} ) , {a}_{4} + \frac{{a}_{4}}{{a}_{4} + {a}_{3}} ( Δ + {a}_{2} ) , {a}_{4} + \frac{{a}_{4}}{{a}_{4} + {a}_{3}} ( Δ + {a}_{1} + {a}_{2} ) \} .$$

Amplitudes a₁, a₂, a₃ and a₄ can be defined to enable an improved power relationship between components in order to increase the combination efficiency at the combiner circuitry and can assume different values belonging to a discrete and limited set of possible values for each combiner type.

The punctured mapper circuitry 308 can be operable to receive the set of quantization amplitude bits 307-1 to 307-N_{b}, the amplitude Aₙ, the phase αₙ or the compensation factor Δ via signal 307-v, the punctured encoding table via signal 306, or the like. Further, the punctured mapper circuitry 308 can be operable to generate an active set of N′≤N_{b} pairs of in-phase and quadrature-phase mapping components according to a mapping table that can be stored in a LUT circuit. The LUT circuitry can be configured to store the mapping component values according to a certain puncturing rule and can include the storage of the quantization amplitude bit combinations, the sets of discrete amplitudes aᵢ, the set of quantized amplitude values, or the like. The punctured mapper circuitry 308 can be operable to select the mapping values of the corresponding mapping components based on the set of quantization amplitude bits and the punctured encoding table 306 to obtain a punctured mapping table such as represented by:

Equivalent Mapping with Component Puncturing

| C₄ | C₃ | C₂ | C₁ |
|---|---|---|---|
| ${C}_{4}^{( 1 )}$ | ${C}_{3}^{( 1 )}$ | ${C}_{2}^{( 1 )}$ | ${C}_{1}^{( 1 )}$ |
| ${C}_{4}^{( 2 )}$ | ${C}_{3}^{( 2 )}$ | ${C}_{2}^{( 2 )}$ | ${C}_{1}^{( 2 )}$ |
| ${C}_{4}^{( 3 )}$ | ${C}_{3}^{( 3 )}$ | ${C}_{2}^{( 3 )}$ | ${C}_{1}^{( 3 )}$ |
| ${C}_{4}^{( 4 )}$ | ${C}_{3}^{( 4 )}$ | ${C}_{2}^{( 4 )}$ | ${C}_{1}^{( 4 )}$ |
| ${C}_{4}^{( 5 )}$ | ${C}_{3}^{( 5 )}$ | ${C}_{2}^{( 5 )}$ | ${C}_{1}^{( 5 )}$ |
| ${C}_{4}^{( 6 )}$ | ${C}_{3}^{( 6 )}$ | ${C}_{2}^{( 6 )}$ | X |
| ${C}_{4}^{( 7 )}$ | ${C}_{3}^{( 7 )}$ | ${C}_{2}^{( 7 )}$ | ${C}_{1}^{( 6 )}$ |
| ${C}_{4}^{( 8 )}$ | ${C}_{3}^{( 8 )}$ | ${C}_{2}^{( 8 )}$ | X |
| ${C}_{4}^{( 9 )}$ | ${C}_{3}^{( 9 )}$ | ${C}_{2}^{( 9 )}$ | ${C}_{1}^{( 7 )}$ |
| ${C}_{4}^{( 10 )}$ | ${C}_{3}^{( 10 )}$ | ${C}_{2}^{( 10 )}$ | X |
| ${C}_{4}^{( 11 )}$ | ${C}_{3}^{( 11 )}$ | X | ${C}_{1}^{( 8 )}$ |
| ${C}_{4}^{( 12 )}$ | ${C}_{3}^{( 12 )}$ | X | X |
| ${C}_{4}^{( 13 )}$ | ${C}_{3}^{( 13 )}$ | ${C}_{2}^{( 11 )}$ | ${C}_{1}^{( 9 )}$ |
| ${C}_{4}^{( 14 )}$ | ${C}_{3}^{( 14 )}$ | ${C}_{2}^{( 12 )}$ | X |
| ${C}_{4}^{( 15 )}$ | ${C}_{3}^{( 15 )}$ | X | ${C}_{1}^{( 10 )}$ |
| ${C}_{4}^{( 16 )}$ | ${C}_{3}^{( 16 )}$ | X | X |

with the coefficients Cₖ, k=1, . . . , N_{b}, to map the quantized value into N′≤N_{b} pairs of in-phase s_{I,n} and quadrature-phase s_{Q,n} mapping components 309-1ᵢ, 309-2ᵢ and 309-1_{q}, 309-2_{q}, given by Cₖ cos(αn) and Cₖ sin(αn) with k=1, . . . , N_{b}. C₁ mapping coefficient can assume values from a set of amplitudes

$${C}_{1}^{( i )} ,$$

i=1, . . . , 10 that belong to a discrete alphabet A₁ with possible values of

$$\{ 0 , Δ , {a}_{1} + Δ , {a}_{1} + \frac{{a}_{1}}{{a}_{2} + {a}_{1}} Δ \} ,$$

where amplitudes a₁ and a₂ can be defined to enable a more favorable power relationship between components to increase energy efficiency. C₂ mapping coefficient can assume values from a set of amplitudes

$${C}_{2}^{( i )} ,$$

i=1, . . . , 12 belonging to a discrete alphabet A₂ with possible values of

$$\{ 0 , {a}_{2} + Δ , {a}_{2} + \frac{{a}_{2}}{{a}_{2} + {a}_{1}} Δ , {a}_{2} + \frac{{a}_{2}}{{a}_{3} + {a}_{2}} Δ , {a}_{2} + \frac{{a}_{2}}{{a}_{3} + {a}_{2}} ( Δ + {a}_{1} ) \} ,$$

where amplitudes a₁, a₂ and a₃ can be defined to enable a more favorable power relation between components to increase energy efficiency. C₃ mapping coefficient can assume values from a set of amplitudes

$${C}_{3}^{( i )} ,$$

i=1, . . . , 16 belonging to a discrete alphabet A₃ with possible values of

$$\{ 0 , {a}_{3} + Δ , {a}_{3} + Δ + {a}_{1} , {a}_{3} + \frac{{a}_{3}}{{a}_{4} + {a}_{3}} Δ , {a}_{3} + \frac{{a}_{3}}{{a}_{4} + {a}_{3}} ( Δ + {a}_{1} ) , {a}_{3} + \frac{{a}_{3}}{{a}_{4} + {a}_{3}} Δ , {a}_{3} + \frac{{a}_{3}}{{a}_{4} + {a}_{3}} ( Δ + {a}_{1} ) , {a}_{3} + \frac{{a}_{3}}{{a}_{4} + {a}_{3}} ( Δ + {a}_{2} ) , {a}_{3} + \frac{{a}_{3}}{{a}_{4} + {a}_{3}} ( Δ + {a}_{1} + {a}_{2} ) \} .$$

C₄ mapping coefficient can assume values from a set of amplitudes

$${C}_{4}^{( i )} ,$$

i=1, . . . 16 belonging to a discrete alphabet A₄ with possible values of

$$\{ 0 , {a}_{4} + Δ , {a}_{4} + Δ + {a}_{1} , {a}_{4} + Δ + {a}_{2} , {a}_{4} + Δ + {a}_{2} + {a}_{1} , {a}_{4} + \frac{{a}_{4}}{{a}_{4} + {a}_{3}} Δ , {a}_{4} + \frac{{a}_{4}}{{a}_{4} + {a}_{3}} ( Δ + {a}_{1} ) , {a}_{4} + \frac{{a}_{4}}{{a}_{4} + {a}_{3}} ( Δ + {a}_{2} ) , {a}_{4} + \frac{{a}_{4}}{{a}_{4} + {a}_{3}} ( Δ + {a}_{1} + {a}_{2} ) \} .$$

Amplitudes a₁, a₂, a₃ and a₄ can be defined to maximize energy efficiency and may assume different values belonging to a discrete and limited set of possible values.

In another embodiment, a LUT circuitry can be configured to store the punctured mapping table, the punctured coding table, the quantization encoding table, the quantization values table, the quantization amplitude components table, or the like. Further, the LUT circuitry can be configured to be accessible by the quantizer encoder circuitry 303, the punctured encoder circuitry 305, the punctured mapper circuitry 308, or the like.

In another embodiment, a single LUT circuitry can be configured to store the punctured mapping table, the punctured coding table, the quantization encoding table, the quantization values table, the quantization amplitude components table, or the like.

In another embodiment, circuitry B1 can be configured to include the punctured mapper circuitry 308, the quantizer encoder circuitry 305, the control information generator circuitry 309-cb, or the like. Further, the circuitry B1 can be implemented in a single circuitry block such as via hardware, software or firmware, including digital or analog techniques and with or without a microprocessor, FPGA, DSP, or the like.

In FIG. 3A, the punctured mapper circuitry 308 can be operable to generate the active set of N′ pairs of in-phase and quadrature-phase mapping components 309-1i, 309-2i and 309-1q, 309-2q and output those components 309-1i, 309-2i and 309-1q, 309-2q to a set of N′ bandpass modulator circuitry 310-1, 310-2 operable to generate the punctured set of N′ bandpass components 311-1, 311-2 at an IF or RF frequency. Without the set of mixer circuitry 312-1, 312-2, the set of bandpass modulator circuitry 310-1, 310-2 (e.g., I/Q DACs, I/Q modulators) can be operable to generate a punctured set of bandpass components having the carrier frequency f_{c}, with signals 311-1, 311-2 having same carrier frequency as signals 313-1, 313-2. Due to puncturing the amplitudes of the mapping components 309-i1 and 309-q1, these components can be associated with the C₁ and C₃ mapping coefficients. Further, the bandpass modulator circuitry 310-1 can be operable to generate bandpass components associated with the C₁ and C₃ mapping coefficients. In addition, the amplitudes of the mapping components 309-i₂ and 309-q₂ can be associated with the C₂ or C₄ mapping coefficients. Accordingly, the bandpass modulator circuitry 310-2 can be operable to generate bandpass components associated with the respective C₂ or C₄ mapping coefficients. The punctured mapper circuitry 308 can also output, to the control information generator circuitry 309-cb, a signal 309-dci that represents the mapping rule applied to each quantized amplitude value. The control information generator circuitry 309-cb can be operable to generate control information to activate or deactivate the set of mixer circuitry 312-1, 312-2 or the set of power amplifier circuitry 316-1 to 316-4 based on the active set of mapping components.

In another embodiment, the set of bandpass modulator circuitry 310-1, 310-2 (e.g., I/Q modulators, I/Q DACs) can be operable to generate the set active bandpass components at the intermediate frequency fᵢ and the set of mixer circuitry 312-1, 312-2 can be operable to up-convert the punctured set of N′ bandpass components to the carrier frequency f_{c}.

In FIG. 3A, a switch circuitry 314-1 can be configured to switch the signal 313-1 for output on branch 315-1 for input to the power amplifier 316-1 or for output on branch 315-2 for input to the power amplifier 316-2 based on a switch selection signal 309-sc and in accordance with the punctured mapping rule determined by the punctured mapper circuitry 308. A switch circuitry 314-2 can be configured to switch the signal 313-2 for output on branch 315-3 for input to the power amplifier 316-3 or for output on branch 315-4 for input to the power amplifier 316-4 based on the switch selection signal 309-sc and in accordance with the punctured mapping rule determined by the punctured mapper circuitry 308. The active set of power amplifier circuitry can be operable to amplify the active set of signals 315-1 or 315-2, 315-3 or 315-4 to obtain the active set of amplified signals 217-1 or 217-2, 217-3 or 217-4. The combiner circuitry 318 is operable to combine the active set of amplified signals 217-1 or 217-2, 217-3 or 217-4 to obtain an output signal 319.

In another embodiment, the control information generator circuitry 309-cb can be operable to determine control information 309-pac to activate or deactivate the set of power amplifier circuitry 316-1, 316-2, 316-3, 316-4. Further, the control information generator circuitry 309-cb can be operable to determine control information 309-cdc to control which of the active set of amplified signals 217-1, 217-2, 217-3, 217-4 is combined to obtain an output signal 319.

In another embodiment, feedback signals output by the set of mixer circuitry 312-1, 312-2 can be input to the punctured mapper circuitry 308 operable to generate phase or time control information for the set of bandpass modulator circuitry 310-1, 310-2 (e.g., I/Q modulators, I/Q DACs) to enable time synchronization or phase synchronization of the punctured set of N′ bandpass components 313-1, 313-2 or to enable time synchronization or phase synchronization of the active set of N′ amplified bandpass components 317-1, 317-2, 317-3, 317-4.

In another embodiment, feedback signals F-1, F-2 can be output by the set of bandpass modulator circuitry 310-1, 310-2 and input to the punctured mapper circuitry 308 operable to generate phase or time control information to enable time synchronization or phase synchronization of the punctured set of N′ bandpass components 313-1, 313-2 or to enable time synchronization or phase synchronization of the active set of N′ amplified bandpass components 317-1, 317-2, 317-3, 317-4.

In another embodiment, the punctured mapper 308 provides the information to control the initial phase of the sinusoidal signals generated by a set of bandpass modulators for each sampling interval.

In another embodiment, feedback signal F1 from the combiner circuitry 318 can be input to the punctured mapper circuitry 308 operable to generate phase or time control information for the set of bandpass modulator circuitry 310-1, 310-2 (e.g., I/Q modulators, I/Q DACs) or to generate digital control information 309-dci for input to the control information generator 309-cb.

In another embodiment, the set of N′ I/Q DACs can be operable to generate the punctured set of bandpass components at the intermediate frequency fᵢ or a set of mixer circuitry can be operable to up-convert the punctured set of bandpass components to the carrier frequency f_{c}.

In FIG. 3A, a local oscillator circuitry 301s-2 can be operable to generate a sinusoidal reference signal 301s-3 at an intermediate frequency or at a frequency associated with up-conversion of the punctured set of bandpass components at the intermediate frequency fᵢ to the carrier frequency f_{c}.

In another embodiment, the circuitry 301s-2 can be operable to generate, based on the reference signal clock 301s-1 at the intermediate frequency fᵢ, a sinusoidal reference signal 301s-3 at the intermediate frequency configured for the set of bandpass modulators 310-1, 310-2 and the input signal 301-f_{c} at the carrier frequency f_{c} can be input to the set of mixer circuitry 312-1, 312-2 to enable up-conversion of the set of bandpass mapping components 311-1, 311-2 at the carrier frequency f_{c}.

In another embodiment, feedback signals Fa-1 to Fa-4 from the set of power amplifiers circuitry 316-1 to 316-4 can also be input to the punctured mapper circuitry 308 operable to generate phase or time control information for the set of bandpass modulator circuitry 310-1, 310-2 (e.g., I/Q modulators or I/Q DACs) to enable time or phase synchronization of the punctured set of bandpass components at the outputs of the active set of power amplifier circuitry 316-1 to 316-4.

FIG. 3B illustrates another embodiment of a system 300b of performing quantized amplification with a reduced set of bandpass modulator circuitry 310-1, 310-2 in accordance with various aspects as described herein. For an even number of the set of quantization bits N_{b} that represent the quantized amplitude of each input signal sample and the number of the set of quantization bits N_{b} being at least four (4) bits, the number of the set of N′ pairs of in-phase and quadrature-phase mapping components 309-1i, 309-2i and 309-1q, 309-2q can be no more than

$${N}^{′} = \frac{{N}_{b}}{2}$$

and the number of bandpass modulator circuitry 310-1, 310-2 can be reduced to N′. As illustrated in FIG. 3A, the number of the set of quantization bits N_{b} that represent the quantized amplitude of each input signal sample is four (4) bits and the number of the set of bandpass modulator circuitry 310-1, 310-2 (e.g., I/Q modulators, I/Q DACs) is reduced to N′ equal to two (2).

In FIG. 3B, the punctured mapper circuitry 308 can be operable to select, based on the set of quantization bits and the punctured encoding table 306, the mapping values of the corresponding mapping components in a punctured mapping table with the coefficients

$${C}_{k}^{( i )} ,$$

k=1, . . . , N_{b} to map the quantized value into N′≤N_{b} pairs of in-phase s_{I,n} and quadrature-phase s_{Q,n} mapping components 309-1i, 309-2i and 309-1q, 309-2q. C₁, C₂ and C₃ mapping coefficients can assume same values of C₁, C₂ and C₃ mapping coefficients such as in the exemplary embodiment of FIG. 3A. Each bandpass modulator circuitry 310-1, 310-2 can be associated by two different sets of mapping coefficients corresponding to the two possible bandpass components that can be generated.

In another embodiment, each bandpass modulator circuitry 310-1, 310-2 can be associated with more than two different sets of mapping coefficients corresponding to the possible bandpass components that can be generated by each bandpass modulator circuitry 310-1, 310-2.

In another embodiment, the punctured mapping table, the punctured coding table, the quantization encoding table, the quantization values table or the quantization amplitude components table can be stored in a LUT circuitry acceptable to the quantizer encoder circuitry 303, the punctured encoder circuitry 305 or the punctured mapper circuitry 308.

In another embodiment, the punctured mapping table, the punctured coding table, the quantization encoding table, the quantization values table or the quantization amplitude components table can be stored in a single LUT circuitry.

In FIG. 3B, the number of the active set of mapping components is no more than two (2), and two (2) bandpass modulator circuitry 310-1, 310-2 are needed. The punctured mapper circuitry 308 can be operable to output the active set of N′ pairs of in-phase and quadrature-phase mapping components 309-1i, 309-1q and 309-2i, 309-2q to the set of N′ I/Q modulator circuitry 310-1, 310-2 operable to generate the punctured set of N′ bandpass components 311-1 or 311-2, 311-3 or 311-4. Without the inclusion of the set of mixer circuitry 312-1 to 312-4 to the system 300b, the set of bandpass modulator circuitry 310-1, 310-2 (e.g., I/Q modulators, I/Q DACs) can be operable to generate a punctured set of bandpass components 311-1 or 311-2, 311-3 or 311-4 at the carrier frequency f_{c}. In the current embodiment, due to puncturing, amplitudes of the mapping signals 309-1i, 309-1q can assume values of the C₁ or C₃ mapping coefficients, and the bandpass modulator circuitry 310-1 can be operable to generate bandpass components associated with the respective C₁ or C₃ mapping coefficients. Further, amplitudes of the mapping signals 309-2i, 309-2q can assume values of the C₂ or C₄ mapping coefficients and the bandpass modulator circuitry 310-2 can be operable to generate bandpass components associated with the respective C₂ or C₄ mapping coefficients. The punctured mapper circuitry 308 can be operable to output, to the control information generator circuitry 309-cb, control information 309-dci associated with the mapping rule applied to each quantized value to enable generation of control information to active or deactivate the set of mixer circuitry 312-1 to 312-4 or the active set of power amplifier circuitry 314-1 to 314-5 associated with the active mapping components.

In another embodiment, the set of bandpass modulator circuitry 310-1, 310-2 can be operable to generate the punctured set of bandpass components at the intermediate frequency fᵢ and the set of mixer circuitry 312-1 to 312-4 are used to up convert the N′ active among bandpass components 311-{1, . . . , N_{b}} to N′ active among bandpass components 313-{1, . . . , N_{b}} at carrier frequency f_{c}.

In FIG. 3B, the signals 313-1 to 313-4 can be amplified by the set of power amplifier circuitry 314-1 to 314-4, respectively. N′ equals two (2) signals among the set of signals 315-1 to 315-4 correspond to the active set of amplified signals (associated with the punctured set of bandpass components 311-1 to 311-4) that are input to the combiner circuitry 316 operable to combine the active set of amplified signals to obtain the output signal 317.

In another embodiment, the control information generator circuitry 309-cb can be operable to generate control information 309-pac to control power amplifier activation or deactivation and control information 309-cdc to control the combiner circuitry 318 of circuitry B2.

In another embodiment, the punctured mapper circuitry 308 can be operable to provide the information to control the initial phase of the sinusoidal signals generated by the set of bandpass modulator circuitry 310-1, 310-2 (e.g., I/Q modulators, I/Q DACs) for each sampling interval.

In another embodiment, the punctured mapper circuitry 308 can be operable to generate time or phase control information for the set of bandpass modulator circuitry 310-1, 310-2, to enable the punctured set of bandpass components 311-1 to 311-4 to be time or phase aligned.

In another embodiment, feedback signal F2 from the combiner circuitry 316 can be input to the punctured mapper circuitry 308 to enable generation of time or phase control information for the set of bandpass modulator circuitry 310-1, 310-2 or generation of digital control information 309-dci for input to the control information generator circuitry 309-cb.

In another embodiment, a local oscillator circuitry 301s-2 can be operable to generate a sinusoidal reference signal 301s-3 having an intermediate frequency or a frequency associated with up-conversion to a carrier frequency f_{c}.

In another embodiment, when the reference signal clock 301s-1 is received with the intermediate frequency fᵢ, circuitry 301s-2 generates a sinusoidal reference signal 301s-3 with the intermediate frequency to be employed in the set of bandpass modulators 310-1, 310-2 and the input signal 301-f_{c} with the carrier frequency f_{c} is used as reference on mixers 312-1, 312-2 operable to up-convert the active bandpass mapping components 311-1, 311-2.

In another embodiment, feedback signals F-a1, F-a2 and F-b1, F-b2 from outputs of the set of bandpass modulators 310-1, 310-2 are provided to the punctured mapper 308 to generate phase or time control information to enable time or phase synchronization of bandpass components.

In another embodiment, feedback signals F-1, F-2 from outputs of the set of mixer circuitry 312-1, 312-2 are provided to the punctured mapper to generate phase and time control information for the set of bandpass modulator circuitry 310-1, 310-2 to enable time or phase synchronization of bandpass components after the mixers' outputs.

In another embodiment, feedback signals Fa-1 to Fa-4 from amplifiers' outputs 315-1 to 315-4 are also provided to the punctured mapper that generates phase and time control information for the bandpass modulators 310-1, 310-2, to assure time and phase synchronization of bandpass components at amplifiers' outputs.

In another embodiment, circuitry B1 having punctured mapper circuitry, quantizer encoder circuitry, and control information generator and said circuitry with a plurality of bandpass modulators can be implemented in a single block by a blend of hardware, software and firmware, including both digital and analog techniques with or without microprocessors, FPGAs and digital signal processors DSPs.

In another embodiment, circuitry B2 can include a combiner circuitry operable to receive a plurality of bandpass components in which it is used the digital control information to activate or deactivate inputs, and generates feedback signals that are sent to the punctured mapper that uses this information to correct the information about the phase and amplitude to enable synchronization of the amplified bandpass combined in the combiner circuitry.

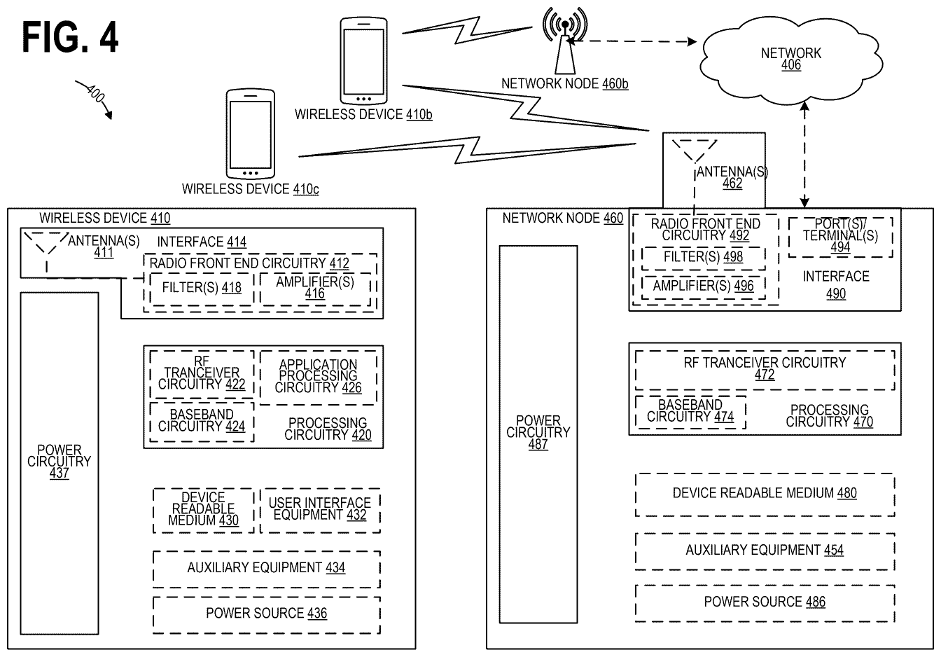

Although the subject matter described herein may be implemented in any appropriate type of system using any suitable components, the embodiments disclosed herein may also be described in relation to a wireless network, such as the example wireless network illustrated in FIG. 4. For simplicity, the wireless network of FIG. 4 only depicts network 406, network nodes 460 and 460b, and wireless devices 410, 410b, and 410c. In practice, a wireless network may further include any additional elements suitable to support communication between wireless devices or between a wireless device and another communication device, such as a landline telephone, a service provider, or any other network node or end device. Of the illustrated components, network node 460 and wireless device 410 are depicted with additional detail. The wireless network may provide communication and other types of services to one or more wireless devices to facilitate the wireless devices' access to and/or use of the services provided by, or via, the wireless network.

The wireless network may comprise and/or interface with any type of communication, telecommunication, data, cellular, and/or radio network or other similar type of system. In some embodiments, the wireless network may be configured to operate according to specific standards or other types of predefined rules or procedures. Thus, particular embodiments of the wireless network may implement communication standards, such as Global System for Mobile Communications (GSM), Universal Mobile Telecommunications System (UMTS), Long Term Evolution (LTE), Narrowband Internet of Things (NB-IoT), and/or other suitable 2G, 3G, 4G, 4G, 4G standards; wireless local area network (WLAN) standards, such as the IEEE 402.11 standards; and/or any other appropriate wireless communication standard, such as the Worldwide Interoperability for Microwave Access (WiMax), Bluetooth, Z-Wave and/or ZigBee standards.

Network 406 may comprise one or more backhaul networks, core networks, IP networks, public switched telephone networks (PSTNs), packet data networks, optical networks, wide-area networks (WANs), local area networks (LANs), wireless local area networks (WLANs), wired networks, wireless networks, metropolitan area networks, and other networks to enable communication between devices.

Network node 460 and wireless device 410 comprise various components described in more detail below. These components work together to provide network node and/or wireless device functionality, such as providing wireless connections in a wireless network. In different embodiments, the wireless network may comprise any number of wired or wireless networks, network nodes, base stations, controllers, wireless devices, relay stations, and/or any other components or systems that may facilitate or participate in the communication of data and/or signals whether via wired or wireless connections.

As used herein, network node refers to equipment capable, configured, arranged and/or operable to communicate directly or indirectly with a wireless device and/or with other network nodes or equipment in the wireless network to enable and/or provide wireless access to the wireless device and/or to perform other functions (e.g., administration) in the wireless network. Examples of network nodes include, but are not limited to, access points (APs) (e.g., radio access points), base stations (BSs) (e.g., radio base stations, Node Bs, evolved Node Bs (eNBs), and NR NodeBs (gNBs)). Base stations may be categorized based on the amount of coverage they provide (or, stated differently, their transmit power level) and may then also be referred to as femto base stations, pico base stations, micro base stations, or macro base stations. A base station may be a relay node or a relay donor node controlling a relay. A network node may also include one or more (or all) parts of a distributed radio base station such as centralized digital units and/or remote radio units (RRUs), sometimes referred to as Remote Radio Heads (RRHs). Such remote radio units may or may not be integrated with an antenna as an antenna integrated radio. Parts of a distributed radio base station may also be referred to as nodes in a distributed antenna system (DAS). Yet further examples of network nodes include multi-standard radio (MSR) equipment such as MSR BSs, network controllers such as radio network controllers (RNCs) or base station controllers (BSCs), base transceiver stations (BTSs), transmission points, transmission nodes, multi-cell/multicast coordination entities (MCEs), core network nodes (e.g., MSCs, MMEs), O&M nodes, OSS nodes, SON nodes, positioning nodes (e.g., E-SMLCs), and/or MDTS. As another example, a network node may be a virtual network node as described in more detail below. More generally, however, network nodes may represent any suitable device (or group of devices) capable, configured, arranged, and/or operable to enable and/or provide a wireless device with access to the wireless network or to provide some service to a wireless device that has accessed the wireless network.

In FIG. 4, network node 460 includes processing circuitry 470, device readable medium 480, interface 490, auxiliary equipment 454, power source 456, power circuitry 457, and antenna 462. Although network node 460 illustrated in the example wireless network of FIG. 4 may represent a device that includes the illustrated combination of hardware components, other embodiments may comprise network nodes with different combinations of components. It is to be understood that a network node comprises any suitable combination of hardware and/or software to perform the tasks, features, functions and methods disclosed herein. Moreover, while the components of network node 460 are depicted as single boxes located within a larger box, or nested within multiple boxes, in practice, a network node may comprise multiple different physical components that make up a single illustrated component (e.g., device readable medium 480 may comprise multiple separate hard drives as well as multiple RAM modules).

Similarly, network node 460 may be composed of multiple physically separate components (e.g., a NodeB component and a RNC component, or a BTS component and a BSC component, etc.), which may each have their own respective components. In certain scenarios in which network node 460 comprises multiple separate components (e.g., BTS and BSC components), one or more of the separate components may be shared among several network nodes. For example, a single RNC may control multiple NodeB's. In such a scenario, each unique NodeB and RNC pair, may in some instances be considered a single separate network node. In some embodiments, network node 460 may be configured to support multiple radio access technologies (RATs). In such embodiments, some components may be duplicated (e.g., separate device readable medium 480 for the different RATs) and some components may be reused (e.g., the same antenna 462 may be shared by the RATs). Network node 460 may also include multiple sets of the various illustrated components for different wireless technologies integrated into network node 460, such as, for example, GSM, wideband code division multiple access (WCDMA), LTE, NR, Wi-Fi, or Bluetooth wireless technologies. These wireless technologies may be integrated into the same or different chip or set of chips and other components within network node 460.

Processing circuitry 470 is configured to perform any determining, calculating, or similar operations (e.g., certain obtaining operations) described herein as being provided by a network node. These operations performed by processing circuitry 470 may include processing information obtained by processing circuitry 470 by, for example, converting the obtained information into other information, comparing the obtained information or converted information to information stored in the network node, and/or performing one or more operations based on the obtained information or converted information, and as a result of said processing making a determination.

Processing circuitry 470 may comprise a combination of one or more of a microprocessor, controller, microcontroller, central processing unit, DSP, application-specific integrated circuitry (ASIC), FPGA, or any other suitable computing device, resource, or combination of hardware, software and/or encoded logic operable to provide, either alone or in conjunction with other network node 460 components, such as device readable medium 480, network node 460 functionality. For example, processing circuitry 470 may execute instructions stored in device readable medium 480 or in memory within processing circuitry 470. Such functionality may include providing any of the various wireless features, functions, or benefits discussed herein. In some embodiments, processing circuitry 470 may include a system on a chip (SOC).

In some embodiments, processing circuitry 470 may include one or more of RF transceiver circuitry 472 and baseband processing circuitry 474. In some embodiments, RF transceiver circuitry 472 and baseband processing circuitry 474 may be on separate chips (or sets of chips), boards, or units, such as radio units and digital units. In alternative embodiments, part or all of RF transceiver circuitry 472 and baseband processing circuitry 474 may be on the same chip or set of chips, boards, or units. The embodiments described by this disclosure can be implemented for the network node 460 in the interface 490 and/or the processing circuitry 470. Further, the embodiments described by this disclosure can be implemented for the wireless device or user equipment 410 in the interface 414 and/or the processing circuitry 420.

In certain embodiments, some or all of the functionality described herein as being provided by a network node, base station, eNB or other such network device may be performed by processing circuitry 470 executing instructions stored on device readable medium 480 or memory within processing circuitry 470. In alternative embodiments, some or all of the functionalities may be provided by processing circuitry 470 without executing instructions stored on a separate or discrete device readable medium, such as in a hard-wired manner. In any of those embodiments, whether executing instructions stored on a device readable storage medium or not, processing circuitry 470 may be configured to perform the described functionality. The benefits provided by such functionality are not limited to processing circuitry 470 alone or to other components of network node 460 but are enjoyed by network node 460 as a whole, and/or by end users and the wireless network generally.

Device readable medium 480 may comprise any form of volatile or non-volatile computer readable memory including, without limitation, persistent storage, solid-state memory, remotely mounted memory, magnetic media, optical media, random access memory (RAM), read-only memory (ROM), mass storage media (for example, a hard disk), removable storage media (for example, a flash drive, a Compact Disk (CD) or a Digital Video Disk (DVD)), and/or any other volatile or non-volatile, non-transitory device readable and/or computer-executable memory devices that store information, data, and/or instructions that may be used by processing circuitry 470. Device readable medium 480 may store any suitable instructions, data or information, including a computer program, software, an application including one or more of logic, rules, code, tables, etc. and/or other instructions capable of being executed by processing circuitry 470 and, utilized by network node 460. Device readable medium 480 may be used to store any calculations made by processing circuitry 470 and/or any data received via interface 490. In some embodiments, processing circuitry 470 and device readable medium 480 may be integrated.

Interface 490 is used in the wired or wireless communication of signaling and/or data between network node 460, network 406, and/or wireless devices 410,410b, 410c. As illustrated, interface 490 comprises port(s)/terminal(s) 494 to send and receive data, for example to and from network 406 over a wired connection. Interface 490 also includes radio front end circuitry 492 that may be coupled to, or in certain embodiments a part of, antenna 462. Radio front end circuitry 492 comprises filters 498 and amplifiers 496. Radio front end circuitry 492 may be connected to antenna 462 and processing circuitry 470. Radio front end circuitry may be configured to condition signals communicated between antenna 462 and processing circuitry 470. Radio front end circuitry 492 may receive digital data that is to be sent out to other network nodes or wireless devices via a wireless connection. Radio front end circuitry 492 may convert the digital data into a radio signal having the appropriate channel and bandwidth parameters using a combination of filters 498 and/or amplifiers 496. The radio signal may then be transmitted via antenna 462. Similarly, when receiving data, antenna 462 may collect radio signals which are then converted into digital data by radio front end circuitry 492. The digital data may be passed to processing circuitry 470. In other embodiments, the interface may comprise different components and/or different combinations of components.

In certain alternative embodiments, network node 460 may not include separate radio front end circuitry 492, instead, processing circuitry 470 may comprise radio front end circuitry and may be connected to antenna 462 without separate radio front end circuitry 492. Similarly, in some embodiments, all or some of RF transceiver circuitry 472 may be considered a part of interface 490. In still other embodiments, interface 490 may include one or more ports or terminals 494, radio front end circuitry 492, and RF transceiver circuitry 472, as part of a radio unit (not shown), and interface 490 may communicate with baseband processing circuitry 474, which is part of a digital unit (not shown).

Antenna 462 may include one or more antennas, or antenna arrays, configured to send and/or receive wireless signals. Antenna 462 may be coupled to radio front end circuitry 490 and may be any type of antenna capable of transmitting and receiving data and/or signals wirelessly. In some embodiments, antenna 462 may comprise one or more omni-directional, sector or panel antennas operable to transmit/receive radio signals between, for example, 2 GHz and 46 GHz. An omni-directional antenna may be used to transmit/receive radio signals in any direction, a sector antenna may be used to transmit/receive radio signals from devices within a particular area, and a panel antenna may be a line-of-sight antenna used to transmit/receive radio signals in a relatively straight line. In some instances, the use of more than one antenna may be referred to as multiple-input multiple-output (MIMO). In certain embodiments, antenna 462 may be separate from network node 460 and may be connectable to network node 460 through an interface or port.

Antenna 462, interface 490, and/or processing circuitry 470 may be configured to perform any receiving operations and/or certain obtaining operations described herein as being performed by a network node. Any information, data and/or signals may be received from a wireless device, another network node and/or any other network equipment. Similarly, antenna 462, interface 490, and/or processing circuitry 470 may be configured to perform any transmitting operations described herein as being performed by a network node. Any information, data and/or signals may be transmitted to a wireless device, another network node and/or any other network equipment.

Power circuitry 487 may comprise, or be coupled to, power management circuitry and is configured to supply the components of network node 460 with power for performing the functionality described herein. Power circuitry 487 may receive power from power source 486. Power source 486 and/or power circuitry 487 may be configured to provide power to the various components of network node 460 in a form suitable for the respective components (e.g., at a voltage and current level for each respective component). Power source 486 may either be included in, or external to, power circuitry 487 and/or network node 460. For example, network node 460 may be connectable to an external power source (e.g., an electricity outlet) via an input circuitry or interface such as an electrical cable, whereby the external power source supplies power to power circuitry 487. As a further example, power source 486 may comprise a source of power in the form of a battery or battery pack which is connected to, or integrated in, power circuitry 487. The battery may provide backup power should the external power source fail. Other types of power sources, such as photovoltaic devices, may also be used.

Alternative embodiments of network node 460 may include additional components beyond those shown in FIG. 4 that may be responsible for providing certain aspects of the network node's functionality, including any of the functionality described herein and/or any functionality necessary to support the subject matter described herein. For example, network node 460 may include user interface equipment to allow input of information into network node 460 and to allow output of information from network node 460. This may allow a user to perform diagnostic, maintenance, repair, and other administrative functions for network node 460.

As used herein, wireless device refers to a device capable, configured, arranged and/or operable to communicate wirelessly with network nodes and/or other wireless devices. Unless otherwise noted, the term wireless device may be used interchangeably herein with user equipment (UE). Communicating wirelessly may involve transmitting and/or receiving wireless signals using electromagnetic waves, radio waves, infrared waves, and/or other types of signals suitable for conveying information through air. In some embodiments, a wireless device may be configured to transmit and/or receive information without direct human interaction. For instance, a wireless device may be designed to transmit information to a network on a predetermined schedule, when triggered by an internal or external event, or in response to requests from the network. Examples of a wireless device include, but are not limited to, a smart phone, a mobile phone, a cell phone, a voice over IP (VOIP) phone, a wireless local loop phone, a desktop computer, a personal digital assistant (PDA), a wireless cameras, a gaming console or device, a music storage device, a playback appliance, a wearable terminal device, a wireless endpoint, a mobile station, a tablet, a laptop, a laptop-embedded equipment (LEE), a laptop-mounted equipment (LME), a smart device, a wireless customer-premise equipment (CPE). a vehicle-mounted wireless terminal device, etc. A wireless device may support device-to-device (D2D) communication, for example by implementing a 3GPP standard for sidelink communication, vehicle-to-vehicle (V2V), vehicle-to-infrastructure (V2I), vehicle-to-everything (V2X) and may in this case be referred to as a D2D communication device. As yet another specific example, in an Internet of Things (IoT) scenario, a wireless device may represent a machine or other device that performs monitoring and/or measurements and transmits the results of such monitoring and/or measurements to another wireless device and/or a network node. The wireless device may in this case be a machine-to-machine (M2M) device, which may in a 3GPP context be referred to as an MTC device. As one example, the wireless device may be a UE implementing the 3GPP narrow band internet of things (NB-IoT) standard. Examples of such machines or devices are sensors, metering devices such as power meters, industrial machinery, or home or personal appliances (e.g. refrigerators, televisions, etc.) personal wearables (e.g., watches, fitness trackers, etc.). In other scenarios, a wireless device may represent a vehicle or other equipment that is capable of monitoring and/or reporting on its operational status or other functions associated with its operation. A wireless device as described above may represent the endpoint of a wireless connection, in which case the device may be referred to as a wireless terminal. Furthermore, a wireless device as described above may be mobile, in which case it may also be referred to as a mobile device or a mobile terminal.

As illustrated, wireless device 410 includes antenna 411, interface 414, processing circuitry 420, device readable medium 430, user interface equipment 432, auxiliary equipment 434, power source 436 and power circuitry 437. Wireless device 410 may include multiple sets of one or more of the illustrated components for different wireless technologies supported by wireless device 410, such as, for example, GSM, WCDMA, LTE, NR, Wi-Fi, WiMAX, NB-IoT, or Bluetooth wireless technologies, just to mention a few. These wireless technologies may be integrated into the same or different chips or set of chips as other components within wireless device 410.

Antenna 411 may include one or more antennas or antenna arrays, configured to send and/or receive wireless signals, and is connected to interface 414. In certain alternative embodiments, antenna 411 may be separate from wireless device 410 and be connectable to wireless device 410 through an interface or port. Antenna 411, interface 414, and/or processing circuitry 420 may be configured to perform any receiving or transmitting operations described herein as being performed by a wireless device. Any information, data and/or signals may be received from a network node and/or another wireless device. In some embodiments, radio front end circuitry and/or antenna 411 may be considered an interface.

As illustrated, interface 414 comprises radio front end circuitry 412 and antenna 411. Radio front end circuitry 412 comprise one or more filters 418 and amplifiers 416. Radio front end circuitry 412 is connected to antenna 411 and processing circuitry 420 and is configured to condition signals communicated between antenna 411 and processing circuitry 420. Radio front end circuitry 412 may be coupled to or a part of antenna 411. In some embodiments, wireless device 410 may not include separate radio front end circuitry 412; rather, processing circuitry 420 may comprise radio front end circuitry and may be connected to antenna 411. Similarly, in some embodiments, some or all of RF transceiver circuitry 422 may be considered a part of interface 414. Radio front end circuitry 412 may receive digital data that is to be sent out to other network nodes or wireless devices via a wireless connection. Radio front end circuitry 412 may convert the digital data into a radio signal having the appropriate channel and bandwidth parameters using a combination of filters 418 and/or amplifiers 416. The radio signal may then be transmitted via antenna 411. Similarly, when receiving data, antenna 411 may collect radio signals which are then converted into digital data by radio front end circuitry 412. The digital data may be passed to processing circuitry 420. In other embodiments, the interface may comprise different components and/or different combinations of components.

Processing circuitry 420 may comprise a combination of one or more of a microprocessor, controller, microcontroller, central processing unit, DSP, ASIC, FPGA, or any other suitable computing device, resource, or combination of hardware, software, and/or encoded logic operable to provide, either alone or in conjunction with other wireless device 410 components, such as device readable medium 430, wireless device 410 functionality. Such functionality may include providing any of the various wireless features or benefits discussed herein. For example, processing circuitry 420 may execute instructions stored in device readable medium 430 or in memory within processing circuitry 420 to provide the functionality disclosed herein.

As illustrated, processing circuitry 420 includes one or more RF transceiver circuitry 422, baseband processing circuitry 424, and application processing circuitry 426. In other embodiments, the processing circuitry may comprise different components and/or different combinations of components. In certain embodiments processing circuitry 420 of wireless device 410 may comprise a SOC. In some embodiments, RF transceiver circuitry 422, baseband processing circuitry 424, and application processing circuitry 426 may be on separate chips or sets of chips. In alternative embodiments, part or all of baseband processing circuitry 424 and application processing circuitry 426 may be combined into one chip or set of chips, and RF transceiver circuitry 422 may be on a separate chip or set of chips. In still alternative embodiments, part or all of RF transceiver circuitry 422 and baseband processing circuitry 424 may be on the same chip or set of chips, and application processing circuitry 426 may be on a separate chip or set of chips. In yet other alternative embodiments, part or all of RF transceiver circuitry 422, baseband processing circuitry 424, and application processing circuitry 426 may be combined in the same chip or set of chips. In some embodiments, RF transceiver circuitry 422 may be a part of interface 414. RF transceiver circuitry 422 may condition RF signals for processing circuitry 420.

In certain embodiments, some or all of the functionality described herein as being performed by a wireless device may be provided by processing circuitry 420 executing instructions stored on device readable medium 430, which in certain embodiments may be a computer-readable storage medium. In alternative embodiments, some or all of the functionalities may be provided by processing circuitry 420 without executing instructions stored on a separate or discrete device readable storage medium, such as in a hard-wired manner. In any of those embodiments, whether executing instructions stored on a device readable storage medium or not, processing circuitry 420 may be configured to perform the described functionality. The benefits provided by such functionality are not limited to processing circuitry 420 alone or to other components of wireless device 410 but are enjoyed by wireless device 410 as a whole, and/or by end users and the wireless network generally.

Processing circuitry 420 may be configured to perform any determining, calculating, or similar operations (e.g., certain obtaining operations) described herein as being performed by a wireless device. These operations, as performed by processing circuitry 420, may include processing information obtained by processing circuitry 420 by, for example, converting the obtained information into other information, comparing the obtained information or converted information to information stored by wireless device 48, and/or performing one or more operations based on the obtained information or converted information, and as a result of said processing making a determination.

Device readable medium 430 may be operable to store a computer program, software, an application including one or more of logic, rules, code, tables, etc. and/or other instructions capable of being executed by processing circuitry 420. Device readable medium 430 may include computer memory (e.g., RAM or ROM), mass storage media (e.g., a hard disk), removable storage media (e.g., CD, DVD), and/or any other volatile or non-volatile, non-transitory device readable and/or computer executable memory devices that store information, data, and/or instructions that may be used by processing circuitry 420. In some embodiments, processing circuitry 420 and device readable medium 430 may be integrated.

User interface equipment 432 may provide components that allow for a human user to interact with wireless device 410. Such interaction may be of many forms, such as visual, audial, tactile, etc. User interface equipment 432 may be operable to produce output to the user and to allow the user to provide input to wireless device 410. The type of interaction may vary depending on the type of user interface equipment 432 installed in wireless device 410. For example, if wireless device 410 is a smart phone, the interaction may be via a touch screen; if wireless device 410 is a smart meter, the interaction may be through a screen that provides usage (e.g., the number of gallons used) or a speaker that provides an audible alert (e.g., if smoke is detected). User interface equipment 432 may include input interfaces, devices and circuits, and output interfaces, devices and circuits. User interface equipment 432 is configured to allow input of information into wireless device 410 and is connected to processing circuitry 420 to allow processing circuitry 420 to process the input information. User interface equipment 432 may include, for example, a microphone, a proximity or other sensor, keys/buttons, a touch display, one or more cameras, a USB port, or other input circuitry. User interface equipment 432 is also configured to allow output of information from wireless device 410, and to allow processing circuitry 420 to output information from wireless device 410. User interface equipment 432 may include, for example, a speaker, a display, vibrating circuitry, a USB port, a headphone interface, or other output circuitry. Using one or more input and output interfaces, devices, and circuits, of user interface equipment 432, wireless device 410 may communicate with end users and/or the wireless network, and allow them to benefit from the functionality described herein.

Auxiliary equipment 434 is operable to provide more specific functionality which may not be generally performed by wireless devices. This may comprise specialized sensors for performing measurements for various purposes, interfaces for additional types of communication such as wired communications etc. The inclusion and type of components of auxiliary equipment 434 may vary depending on the embodiment and/or scenario.

Power source 436 may, in some embodiments, be in the form of a battery or battery pack. Other types of power sources, such as an external power source (e.g., an electricity outlet), photovoltaic devices or power cells, may also be used. The wireless device 410 may further comprise power circuitry 437 for delivering power from power source 436 to the various parts of wireless device 410 which need power from power source 436 to carry out any functionality described or indicated herein. Power circuitry 437 may in certain embodiments comprise power management circuitry. Power circuitry 437 may additionally or alternatively be operable to receive power from an external power source; in which case wireless device 410 may be connectable to the external power source (such as an electricity outlet) via input circuitry or an interface such as an electrical power cable. Power circuitry 437 may also, in certain embodiments, be operable to deliver power from an external power source to power source 436. This may be, for example, for the charging of power source 436. Power circuitry 437 may perform any formatting, converting, or other modification to the power from power source 436 to make the power suitable for the respective components of wireless device 410 to which power is supplied.

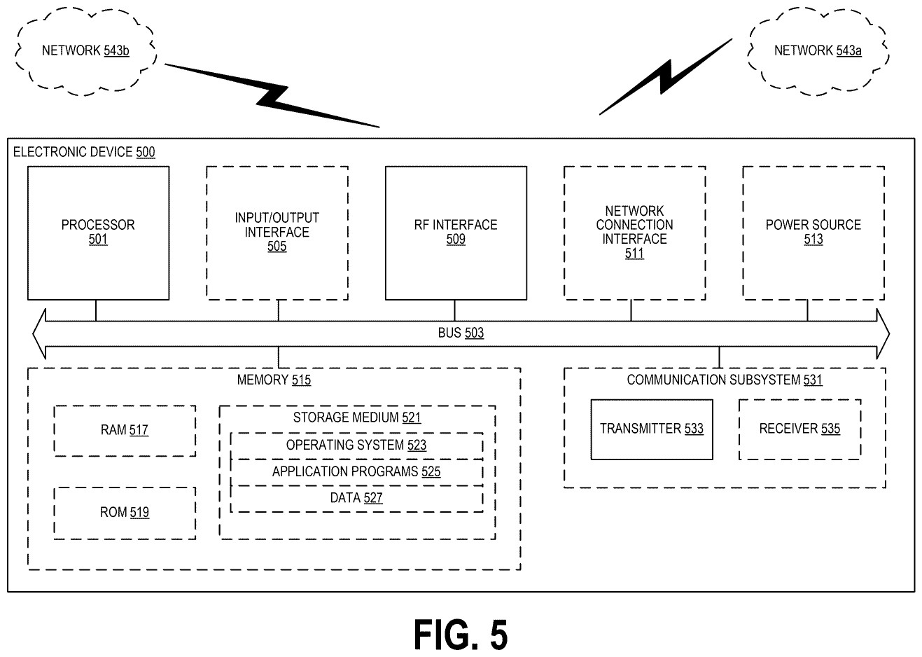

FIG. 5 illustrates one embodiment of an electronic device 500 in accordance with various aspects described herein. As used herein, device 500 can be a wired device, wireless device or both. Further, device 500 may not necessarily have a user in the sense of a human user who owns and/or operates the relevant device. Instead, device 500 may represent a device that is intended for sale to, or operation by, a human user but which may not, or which may not initially, be associated with a specific human user (e.g., a smart sprinkler controller, IoT device). Alternatively, device 500 may represent a device that is not intended for sale to, or operation by, an end user but which may be associated with or operated for the benefit of a user (e.g., a smart power meter). Device 500 may be UE identified by the 3rd Generation Partnership Project (3GPP), including a NB-IoT UE, a machine type communication (MTC) UE, and/or an enhanced MTC (eMTC) UE. Device 500, as illustrated in FIG. 5, is one example of a device configured for wired or wireless communication in accordance with one or more communication standards such as promulgated by the 3rd Generation Partnership Project (3GPP), such as 3GPP's GSM, UMTS, LTE, and/or 5G standards.

Device 500 can include any electronic device that has an amplifier. In one example, device 500 can include an audio or music device, home audio system, stereo amplifier, audio or video receiver, home theater system, powered speaker, subwoofer, karaoke machine, musical equipment, guitar amplifier, bass amplifier, keyboard amplifier, public address (PA) system, studio monitor, headphone or earbud, noise-canceling headphone, portable audio device, Bluetooth speaker, portable amplifier for headphones or instrument, or the like. In another example, device 500 can include a wireless device, user equipment, network node, base station, broadcast or communication device, radio transmitter, wireless communication equipment, satellite communication system, Wi-Fi router, extended range device, telecommunication device, microwave repeater, radar system, or the like. In yet another example, device 500 can include consumer electronics, televisions, internal audio amplifier for a speaker, external soundbar with built-in amplifier, computer or gaming device, sound card with integrated amplifier, DAC with amplifier, smartphone, tablet, built-in audio amplifier for speaker or headphone, or the like. In yet another example, device 500 can include automotive or transportation device, car audio system, car amplifier, subwoofer amplifier, marine audio system, amplifier for boat or watercraft, aircraft communication system, amplifier for cockpit communication or in-flight entertainment, or the like. In yet another example, device 500 can include industrial and professional equipment, public address system, amplifier for a large venue, school or stadium, concert or event equipment, power amplifier for a loudspeaker, line array system, medical equipment, ultrasound machine, hearing aids, or the like. In yet another example, device 500 can include RF or specialized equipment, RF amplifier, signal booster for a cell tower, satellite uplink or downlink device, test or measurement instrument, oscilloscope, spectrum analyzer, military or aerospace equipment, radar system, communication jammer, or the like. In yet another example, device 500 can include toy or hobby device, radio-controlled car, plane or drone, smart home device, smart speaker, voice assistant device, or the like.

In FIG. 5, device 500 includes processing circuitry 501 that is operatively coupled to input/output interface 505, RF interface 509, network connection interface 511, memory 515 including RAM 517, ROM 519, and storage medium 521 or the like, communication subsystem 531, power source 513, and/or any other component, or any combination thereof. Storage medium 521 includes operating system 523, application program 525, and data 527. In other embodiments, storage medium 521 may include other similar types of information. Certain electronic devices may utilize all of the components shown in FIG. 5, or only a subset of the components. The level of integration between the components may vary from one device to another device. Further, certain electronic devices may contain multiple instances of a component, such as multiple processors, memories, transceivers, transmitters, receivers, etc.

In FIG. 5, processing circuitry 501 may be configured to process computer instructions and data. Processing circuitry 501 may be configured to implement any sequential state machine operative to execute machine instructions stored as machine-readable computer programs in the memory, such as one or more hardware-implemented state machines (e.g., in discrete logic, FPGA, ASIC, etc.); programmable logic together with appropriate firmware; one or more stored program, general-purpose processors, such as a microprocessor or DSP, together with appropriate software; or any combination of the above. For example, the processing circuitry 501 may include two central processing units (CPUs). Data may be information in a form suitable for use by a computer.

In the depicted embodiment, input/output interface 505 may be configured to provide a communication interface to an input device, output device, or input and output device. Device 500 may be configured to use an output device via input/output interface 505. An output device may use the same type of interface port as an input device. For example, a USB port may be used to provide input to and output from device 500. The output device may be a speaker, a sound card, a video card, a display, a monitor, a printer, an actuator, an emitter, a smartcard, another output device, or any combination thereof. Device 500 may be configured to use an input device via input/output interface 505 to allow a user to capture information into device 500. The input device may include a touch-sensitive or presence-sensitive display, a camera (e.g., a digital camera, a digital video camera, a web camera, etc.), a microphone, a sensor, a mouse, a trackball, a directional pad, a trackpad, a scroll wheel, a smartcard, and the like. The presence-sensitive display may include a capacitive or resistive touch sensor to sense input from a user. A sensor may be, for instance, an accelerometer, a gyroscope, a tilt sensor, a force sensor, a magnetometer, an optical sensor, a proximity sensor, another like sensor, or any combination thereof. For example, the input device may be an accelerometer, a magnetometer, a digital camera, a microphone, or an optical sensor.

In FIG. 5, RF interface 509 may be configured to provide a communication interface to RF components such as a transmitter, a receiver, and an antenna. Network connection interface 511 may be configured to provide a communication interface to network 543a. Network 543a may encompass wired and/or wireless networks such as a local-area network (LAN), a wide-area network (WAN), a computer network, a wireless network, a telecommunications network, another like network or any combination thereof. For example, network 543a may comprise a Wi-Fi network. Network connection interface 511 may be configured to include a receiver and a transmitter interface used to communicate with one or more other devices over a communication network according to one or more communication protocols, such as Ethernet, TCP/IP, synchronous optical networking (SONET), asynchronous transfer mode (ATM), or the like. Network connection interface 511 may implement receiver and transmitter functionality appropriate to the communication network links (e.g., optical, electrical, and the like). The transmitter and receiver functions may share circuitry components, software or firmware, or alternatively may be implemented separately.

RAM 517 may be configured to interface via bus 502 to processing circuitry 501 to provide storage or caching of data or computer instructions during the execution of software programs such as the operating system, application programs, and device drivers. ROM 519 may be configured to provide computer instructions or data to processing circuitry 501. For example, ROM 519 may be configured to store invariant low-level system code or data for basic system functions such as basic input and output (I/O), startup, or reception of keystrokes from a keyboard that are stored in a non-volatile memory. Storage medium 521 may be configured to include memory such as RAM, ROM, programmable ROM (PROM), erasable PROM (EPROM), electrically erasable PROM (EEPROM), magnetic disks, optical disks, floppy disks, hard disks, removable cartridges, or flash drives. In one example, storage medium 521 may be configured to include operating system 523, application program 525 such as a web browser application, a widget or gadget engine or another application, and data file 527. Storage medium 521 may store, for use by device 500, any of a variety of various operating systems or combinations of operating systems.

Storage medium 521 may be configured to include a number of physical drive units, such as redundant array of independent disks (RAID), floppy disk drive, flash memory, USB flash drive, external hard disk drive, thumb drive, pen drive, key drive, high-density DVD (HD-DVD) optical disc drive, internal hard disk drive, Blu-Ray optical disc drive, holographic digital data storage (HDDS) optical disc drive, external mini-dual in-line memory module (DIMM), synchronous dynamic random access memory (SDRAM), external micro-DIMM SDRAM, smartcard memory such as a subscriber identity module or a removable user identity (SIM/RUIM) module, other memory, or any combination thereof. Storage medium 521 may allow device 500 to access computer-executable instructions, application programs or the like, stored on transitory or non-transitory memory media, to off-load data, or to upload data. An article of manufacture, such as one utilizing a communication system may be tangibly embodied in storage medium 521, which may comprise a device readable medium.

In FIG. 5, processing circuitry 501 may be configured to communicate with network 543b using communication subsystem 531. Network 543a and network 543b may be the same network or networks or different network or networks. Communication subsystem 531 may be configured to include one or more transceivers used to communicate with network 543b. For example, communication subsystem 531 may be configured to include one or more transceivers used to communicate with one or more remote transceivers of another device capable of wireless communication such as another electronic device, wireless device, UE, or base station of a radio access network (RAN) according to one or more communication protocols, such as IEEE 802.11, CDMA, WCDMA, GSM, LTE, UMTS terrestrial radio access network (UTRAN), WiMax, or the like. Each transceiver may include transmitter 533 and/or receiver 535 to implement transmitter or receiver functionality, respectively, appropriate to the RAN links (e.g., frequency allocations and the like). Further, transmitter 533 and receiver 535 of each transceiver may share circuitry components, software or firmware, or alternatively may be implemented separately.

In the illustrated embodiment, the communication functions of communication subsystem 531 may include data communication, voice communication, multimedia communication, short-range communications such as Bluetooth, near-field communication, location-based communication such as the use of the global positioning system (GPS) to determine a location, another like communication function, or any combination thereof. For example, communication subsystem 531 may include cellular communication, Wi-Fi communication, Bluetooth communication, and GPS communication. Network 543b may encompass wired and/or wireless networks such as a LAN, a WAN, a computer network, a wireless network, a telecommunications network, another like network or any combination thereof. For example, network 543b may be a cellular network, a Wi-Fi network, and/or a near-field network. Power source 513 may be configured to provide alternating current (AC) or direct current (DC) power to components of device 500.

The features, benefits and/or functions described herein may be implemented in one of the components of device 500 or partitioned across multiple components of device 500. Further, the features, benefits, and/or functions described herein may be implemented in any combination of hardware, software or firmware. In one example, communication subsystem 531 may be configured to include any of the components described herein. Further, processing circuitry 501 may be configured to communicate with any of such components over bus 502. In another example, any of such components may be represented by program instructions stored in memory that when executed by processing circuitry 501 perform the corresponding functions described herein. In another example, the functionality of any of such components may be partitioned between processing circuitry 501 and communication subsystem 531. In another example, the non-computationally intensive functions of any of such components may be implemented in software or firmware and the computationally intensive functions may be implemented in hardware. The embodiments described by this disclosure can be implemented for the device 500 in the RF interface block 509 or the transmitter block 533 of the communication subsystem 531.

Those skilled in the art will also appreciate that embodiments herein further include corresponding computer programs.

A computer program comprises instructions which, when executed on at least one processor of an apparatus, cause the apparatus to carry out any of the respective processes described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of an apparatus, cause the apparatus to perform as described above.

Embodiments further include a computer program product comprising program code portions for performing the steps of any of the embodiments herein when the computer program product is executed by a computing device. This computer program product may be stored on a computer readable recording medium.

Additional embodiments will now be described. At least some of these embodiments may be described as applicable in certain contexts for illustrative purposes, but the embodiments are similarly applicable in other contexts not explicitly described.

In one exemplary embodiment, a method of performing quantized digital amplification with a reduced number of bandpass modulators includes receiving as input signal samples sₙ of a baseband signal sₙ=s(tₙ)=s_{I,n}+js_{Q,n}, where s_{In} and s_{Qn} represent the sample of the in-phase and quadrature component respectively, and tₙ is the sampling instant; receiving clock reference signals with a value of a carrier frequency (f_{c}), with a sampling rate fₛ and with an intermediate frequency fᵢ; computing for each sample the values

$${A}_{n} = \sqrt{{s}_{1 , n}^{2} + {s}_{Q , n}^{2}} , {α}_{n} = ATAN ( {s}_{Q , n} / {s}_{1 , n} ) ,$$

and quantizing Aₙ using N_{b} quantization bit as A_{qn}=Aₙ+e_{q}, where e_{q} denotes the quantization error and based on quantization error e_{q} computing a compensation factor Δ belonging to a finite discrete alphabet; generating a puncturing encoding table of quantization bits by puncturing quantization bits and generating a punctured mapping table with the puncturing mapping rule; generating, by a punctured mapper circuitry, a set of N′≤N_{b} active pairs of in-phase and quadrature mapping components according to the punctured mapping table that contains the mapping components values with puncturing of components; generating control information to turn off punctured mapping components and control information for selection of components to be amplified, synchronization and switching control; delivering the N′ active pairs of in-phase and quadrature mapping components to a set of bandpass modulators to generate a punctured set of N′ bandpass components at carrier frequency f_{c}; or amplifying the punctured set of N′ bandpass components by a set of N′ active amplifiers.

In another exemplary embodiment, the method step of receiving the input signal can include receiving samples sₙ of a baseband signal s(t) and generating the samples s_{In} and s_{Qn} of the in-phase and quadrature components.

In another exemplary embodiment, the method step of receiving the input signal can include receiving a baseband signal and sampling it in a sampling circuitry or in a sample and hold (S/H) circuitry to obtain samples of the input signal.

In another exemplary embodiment, the method step of receiving the input signal can include receiving samples of in-phase and quadrature-phase components of a baseband signal.

In another exemplary embodiment, the method step of receiving the clock reference signals can include receiving clock reference signals having a carrier frequency f_{c} and a sampling rate fₛ.

In another exemplary embodiment, the quantizing step can be further based on a quantization encoding table with N_{b} bits, a table with the finite set of quantization values, a table with the discrete amplitudes of quantization components aᵢ={a₁, a₂, . . . , a_{Nb}} in which the quantized value can be decomposed, or a punctured quantization encoding table.

In another exemplary embodiment, the mapping table can be stored in a LUT circuitry and can include the mapping components values according to a puncturing rule, the quantization bits combinations, the sets of discrete amplitudes aᵢ, or the set of quantized amplitude values.

In another exemplary embodiment, the method can further include selecting, by the punctured mapper circuitry, the mapping coefficients Cₖ, k=1, . . . , N_{b}, configured to map the quantized amplitude value into N′≤N_{b} pairs of in-phase s_{I,n} and quadrature-phase s_{Q,n} mapping components given by Cₖ cos(αn) and Cₖ sin(αn) with k=1, . . . , N, and in which the amplitude of the mapping coefficients Cₖ assume values from N_{b} discrete alphabets, based on the set of quantization amplitude bits and the punctured encoding table.

In another exemplary embodiment, the method can further include generating, by the punctured mapper circuitry, control information to activate or deactivate the set of mapping components to obtain the punctured set of bandpass components and to control switch circuitry to activate or deactivate the set of power amplifier circuitry to amplify the activated set of mapping components.

In another exemplary embodiment, the set of bandpass modulator circuitry can include a set of N′ I/Q modulators circuitry or a set of N′ I/Q DAC circuitry.

In another exemplary embodiment, the set of N′ bandpass modulator circuitry can be operable to generate the set of N′ active bandpass components at the intermediate frequency fᵢ and the set of N′ mixers can be operable to up-convert the set of N′ active bandpass components to the carrier frequency f_{c}.

In another exemplary embodiment, the punctured mapper circuitry can be operable to determine control information to control the initial phase of the punctured set of bandpass components generated by the set of bandpass modulator circuitry such as by changing the phases or delays of the inputs at the beginning of each sampling interval.

In another exemplary embodiment, the method step of generating control information can include generating control information to control a combiner circuitry operable to combine the set of amplified signals at the output of the active set of power amplifier circuitry.

In another exemplary embodiment, the method can include computing an amplitude Aₙ of the input signal sample, quantizing the amplitude Aₙ, generating the punctured quantization encoding table, performing the punctured mapping rule and the punctured mapping in a single step using LUT circuitry having the corresponding quantization amplitude values, puncturing quantization encoding rule, punctured mapping rules, and the control information.

In another exemplary embodiment, for the number of the set of quantization bits N_{b} that represent the quantized amplitude of the input signal sample being an odd number, the number of active mapping components is no more than

$${N}^{′} = \frac{{N}_{b} + 1}{2}$$

and the maximum number of bandpass modulators is reduced to N′.

In another exemplary embodiment, for the number of the set of quantization bits N_{b} that represent the quantized amplitude of the input signal sample being an even number, the number of active mapping components is no more than

$${N}^{′} = \frac{{N}_{b}}{2}$$

and the maximum number of bandpass modulators is reduced to N′.

In another exemplary embodiment, the method can include combining the punctured set of N′ bandpass components based on the digital control information that represents which components are active or inactive.

In another exemplary embodiment, each bandpass modulator circuitry is associated with more than two different sets of mapping coefficients corresponding to the possible bandpass components that can be generated by each bandpass modulator circuitry.

In one exemplary embodiment, an apparatus configured to perform quantized digital amplification with a reduced set of bandpass modulator circuitry includes an input circuitry operable to receive input signal samples sₙ of a baseband signal sₙ=s(tₙ)=s_{I,n}+js_{Q,n}, where s_{In} and s_{Qn} represent the sample of the in-phase and quadrature component respectively, and tₙ is the sampling instant; an input circuitry operable to receive a clock reference signal having a carrier frequency (f_{c}), a clock reference signal with a sampling rate fₛ or a clock reference signal with an intermediate frequency fᵢ; a quantizer encoding circuitry operable to compute, for each sample sₙ, amplitude Aₙ and phase αₙ, based on a quantization encoding table having a set of N_{b} quantization bits for each quantized amplitude value, a table with a finite set of quantization values, a table with sets of discrete amplitudes of quantization components aᵢ={a₁, a₂, . . . , a_{Nb}} in which the quantized value can be decomposed or the set of quantized values, the quantized value A_{qn}=Aₙ+e_{q}, to obtain the set of quantization bits, or to compute a compensation factor Δ belonging to a finite discrete alphabet based on the quantization error e_{q}; a punctured encoder circuitry operable to generate a punctured encoding table based on the quantization encoding table; a punctured mapper circuitry operable to generate a punctured mapping table that represents the puncturing mapping rule based on the set of quantization bits, the amplitude Aₙ, the phase αₙ, the compensation factor Δ, amplitudes aᵢ or punctured encoding table, to generate an active set of N′≤N_{b} pairs of in-phase and quadrature-phase mapping components, or to select the mapping values of the corresponding mapping components on the punctured mapping table with the coefficients Cₖ, k=1, . . . , N_{b}, to map the quantized value into a set of N′≤N_{b} pairs of in-phase s_{I,n} and quadrature-phase s_{Q,n} mapping components given by Cₖ cos(αn) and Cₖ sin(αn) with k=1, . . . , N_{b}; a set of N′ bandpass modulator circuitry operable to quadrature modulate the active set of N′ pairs of in-phase and quadrature-phase mapping components to obtain the punctured set of N′ bandpass components at the carrier frequency; a set of N′ power amplifiers operable to amplify the punctured set of N′ bandpass components.

In another exemplary embodiment, a sampling circuitry can be operable to sample the input baseband signal to obtain the in-phase and quadrature-phase samples s_{In} and s_{Qn}.

In another exemplary embodiment, the apparatus can be configured to receive the samples s_{In} and s_{Qn} of the in-phase and quadrature-phase components of a baseband signal.

In another exemplary embodiment, clock reference signals can be input to the quantization encoding circuitry, the punctured encoder circuitry, the punctured mapper circuitry, the set of bandpass modulator circuitry, the set of power amplifiers or the combiner circuitry.

In another exemplary embodiment, the punctured mapper circuitry can be operable to output, to the digital control circuitry, control information to enable determination of the digital control signals configured to activate or deactivate the set of power amplifier circuitry, the set of bandpass modulator circuitry, the set of mixer circuitry, or the inputs to the combiner circuitry.

In another exemplary embodiment, when the set of N_{b} quantization bits equals three (3) bits, then the punctured mapping table can include a set of mapping coefficients Cₖ, k=1, . . . , 3 and

$${N}^{′} = \frac{{N}_{b} + 1}{2} = two ( 2 )$$

bandpass modulators; C₁ mapping coefficient can assume values from a set of amplitudes

$${C}_{1}^{( i )} ,$$

i=1, . . . , 6, that belong to a discrete alphabet A₁ with possible values of

$$\{ 0 , Δ , {a}_{1} + Δ , {a}_{1} + \frac{{a}_{1}}{{a}_{2} + {a}_{1}} Δ \} ,$$

where Δ is the discrete compensation factor with values belonging to a discrete and finite alphabet and amplitudes a₁ and a₂ defined to allow the best power relation between components to maximize efficiency and assumes different values belonging to a discrete and limited set of possible values; C₂ mapping coefficient can assume values from a set of amplitudes

$${C}_{2}^{( i )} ,$$

i=1, . . . , 8, belonging to a discrete alphabet A₂ with possible values of

$$\{ 0 , {a}_{2} + Δ , {a}_{2} + \frac{{a}_{2}}{{a}_{2} + {a}_{1}} Δ , {a}_{2} + \frac{{a}_{2}}{{a}_{3} + {a}_{2}} Δ , {a}_{2} + \frac{{a}_{2}}{{a}_{3} + {a}_{2}} ( Δ + {a}_{1} ) \} ,$$

with amplitudes a₁, a₂ and a₃ defined to enable an improved power relationship between components to increase efficiency and assumes different values belonging to a discrete and limited set of possible values; C₃ mapping coefficient can assume values from a set of amplitudes

$${C}_{3}^{( i )} ,$$

i=1, . . . , 8, belonging to a discrete alphabet A₃ with possible values of

$$\{ 0 , {a}_{3} + Δ , {a}_{3} + Δ + {a}_{1} , {a}_{3} + \frac{{a}_{3}}{{a}_{3} + {a}_{2}} Δ , {a}_{3} + \frac{{a}_{3}}{{a}_{3} + {a}_{2}} ( Δ + {a}_{1} ) \} ,$$

where amplitudes a₁, a₂ and a₃ are defined to increase efficiency and assume different values belonging to a finite discrete set of possible values; or a single bandpass modulator operable to generate bandpass components associated with C₁ or C₃ mapping coefficients, and a single bandpass modulator operable to generates a bandpass component associated with C₂ mapping coefficient.

In another exemplary embodiment, when the set of N_{b} quantization bits equals four (4) bits, a punctured mapping table can be configured to include a set of mapping coefficients Cₖ, k=1, . . . , 4 and

$${N}^{′} = \frac{{N}_{b}}{2} = 2$$

bandpass modulators; C₁ mapping coefficient can assume values from a set of amplitudes

$${C}_{1}^{( i )} ,$$

i=1, . . . , 10, that belong to a discrete alphabet A₁ with possible values of

$$\{ 0 , Δ , {a}_{1} + Δ , {a}_{1} + \frac{{a}_{1}}{{a}_{2} + {a}_{1}} Δ \} ,$$

where Δ is the discrete compensation factor with values belonging to a discrete and finite alphabet, and amplitudes a₁ and a₂ defined to enable an improved power relationship between components to increase energy efficiency; C₂ mapping coefficient can assume values from a set of

$${C}_{2}^{( i )} ,$$

i=1, . . . , 12 belonging to a discrete alphabet A₂ with possible values of

$$\{ 0 , {a}_{2} + Δ , {a}_{2} + \frac{{a}_{2}}{{a}_{2} + {a}_{1}} Δ , {a}_{2} + \frac{{a}_{2}}{{a}_{3} + {a}_{2}} Δ , {a}_{2} + \frac{{a}_{2}}{{a}_{3} + {a}_{2}} ( Δ + {a}_{1} ) \} ,$$

with amplitudes a₁, a₂ and a₃ defined to enable an improved power relationship between components to increase energy efficiency; C₃ mapping coefficient can assume values from a set of amplitudes

$${C}_{3}^{( i )} ,$$

i=1, . . . , 16 belonging to a discrete alphabet A₃ with possible values of

$$\{ 0 , {a}_{3} + Δ , {a}_{3} + Δ + {a}_{1} , {a}_{3} + \frac{{a}_{3}}{{a}_{4} + {a}_{3}} Δ , {a}_{3} + \frac{{a}_{3}}{{a}_{4} + {a}_{3}} ( Δ + {a}_{1} ) , {a}_{3} + \frac{{a}_{3}}{{a}_{4} + {a}_{3}} Δ , {a}_{3} + \frac{{a}_{3}}{{a}_{4} + {a}_{3}} ( Δ + {a}_{1} ) , {a}_{3} + \frac{{a}_{3}}{{a}_{4} + {a}_{3}} ( Δ + {a}_{2} ) , {a}_{3} + \frac{{a}_{3}}{{a}_{4} + {a}_{3}} ( Δ + {a}_{1} + {a}_{2} ) \} ,$$

where amplitudes a₁, a₂, a₃ and a₄ are defined to enable an improved power relationship between components in order to increase energy efficiency; C₄ mapping coefficient can assume values from a set of amplitudes

$${C}_{4}^{( i )} ,$$

i=1, . . . , 16 belonging to a discrete alphabet A₄ with possible values of

$$\{ 0 , {a}_{4} + Δ , {a}_{4} + Δ + {a}_{1} , {a}_{4} + Δ + {a}_{2} , {a}_{4} + Δ + {a}_{2} + {a}_{1} , {a}_{4} + \frac{{a}_{4}}{{a}_{4} + {a}_{3}} Δ , {a}_{4} + \frac{{a}_{4}}{{a}_{4} + {a}_{3}} ( Δ + {a}_{1} ) , {a}_{4} + \frac{{a}_{4}}{{a}_{4} + {a}_{3}} ( Δ + {a}_{2} ) , {a}_{4} + \frac{{a}_{4}}{{a}_{4} + {a}_{3}} ( Δ + {a}_{1} + {a}_{2} ) \} ,$$

where amplitudes a₁, a₂, a₃ and a₄ are defined to enable an improved power relationship between components in order to increase energy efficiency; or a single bandpass modulator operable to generates bandpass components associated with C₁ or C₃ mapping coefficients, and a single bandpass modulator operable to generate bandpass component associated with C₂ or C₄ mapping coefficients.

In another exemplary embodiment, when the set of N_{b} quantization bits equals an even number of bits, the punctured mapping table can include a set of coefficients Cₖ, k=1, . . . , N_{b} with values belonging to N_{b} discrete alphabets Aₖ, k=1, . . . , N_{b}; N′=N_{b}/2 bandpass modulators generate two different bandpass components according to mapping coefficients provided by punctured mapper, with only one active according to the punctured mapping rule.

In another exemplary embodiment, when the set of N_{b} quantization bits equals an odd number of bits, the punctured mapping table can include a set of coefficients Cₖ, k=1, . . . , N_{b} with values belonging to N_{b} discrete alphabets Aₖ, k=1, . . . , N_{b}; N′=N_{b}/2−1 bandpass modulators generate two different bandpass components according to mapping coefficients provided by punctured mapper, with only one active according to the punctured mapping rule; or a single bandpass modulator operable to generate one bandpass component according to mapping coefficients provided by punctured mapper.

In another exemplary embodiment, the punctured mapping table, the punctured coding table, the quantization encoding table, the quantization values table or the quantization amplitude components table can be stored in LUT circuitry that is accessible by the quantizer circuitry, the punctured encoder circuitry or the punctured mapper circuitry.

In another exemplary embodiment, the bandpass modulators can include I/Q modulators having two outputs or I/Q DACs having two outputs with each one of the outputs being coupled to a power amplifier for the bandpass mapping component associated with each output.

In another exemplary embodiment, the bandpass modulators can include I/Q modulators or I/Q DACs, with each one having one output coupled to a switch circuitry operable to select the power amplifier for the active bandpass component at the output.

In another exemplary embodiment, the set of bandpass modulators can be operable to generate the set of N′ active bandpass components at intermediate frequency fᵢ and the set of mixers can be operable to up-convert the N′ active bandpass components to the carrier RF frequency f_{c}.

In another exemplary embodiment, each bandpass modulator can be associated with more than two different sets of mapping coefficients corresponding to the possible bandpass components that can be generated by that bandpass modulator.

In another exemplary embodiment, the punctured mapper circuitry, the quantizer encoding circuitry, the set of mixers, or the bandpass modulators can be implemented in hardware, software or firmware, including digital or analog techniques with or without a microprocessor, an FPGA or a DSP.

In another exemplary embodiment, switches coupled to the input of the amplifiers can be controlled by a control signal that includes information associated with which bandpass component is active or inactive and the corresponding amplification branch.

In another exemplary embodiment, the control circuitry can be further operable to generate control information to active or deactivate mixers, control switches or activate power amplifiers corresponding to the active mapping components.

In another exemplary embodiment, the feedback signals from the bandpass modulators can be input to the punctured mapper to enable it to generate time or phase control information for these bandpass modulators, so as to time or phase synchronize the active RF bandpass components at mixers outputs or at amplifiers outputs.

In another exemplary embodiment, the feedback signals from amplifiers' outputs can be input to the punctured mapper to enable it to generate time or phase control information for the bandpass modulators, so as to time or phase synchronize the bandpass components at amplifiers' outputs.

In another exemplary embodiment, the feedback signals from the outputs of mixers can be input to punctured mapper to enable it to time or phase synchronize the active RF bandpass components or amplified bandpass components.

In another exemplary embodiment, when N_{b} is an odd number, the number of bandpass modulators can be no more than

$${N}^{′} = \frac{{N}_{b} + 1}{2}$$

and when N_{b} is an even number, the number of bandpass modulators can be no more than

$${N}^{′} = \frac{{N}_{b}}{2} .$$

In another exemplary embodiment, a combiner circuitry can be operable to receive the punctured set of bandpass components to enable the digital control information to activate or deactivate the inputs, and applies the information associated with synchronization from the punctured mapper. Further, the combiner circuitry can be operable to generate feedback signals that are sent to the punctured mapper that uses this information to correct the information about the phase and amplitude to enable synchronization of the amplified bandpass combined in the combiner circuitry.

In one exemplary embodiment, a method is performed by a user equipment device having a set of bandpass modulator circuitry electrically coupled to a set of power amplifier circuitry. The method includes outputting, by the set of bandpass modulator circuitry, a punctured set of bandpass components that collectively represents a sample of an input signal having information and amplifying, by the set of power amplifier circuitry, the punctured set of bandpass components. Further, the punctured set of bandpass components corresponds to the set of power amplifier circuitry and is associated with a set of quantized bits that represents a quantized amplitude of a polar representation of the input signal sample. In addition, the number of the set of bandpass modulator circuitry is less than the number of the set of quantized bits that represents that quantized amplitude.

In another exemplary embodiment, each bandpass component is associated with one of the set of quantization bits that represents the quantized amplitude of the polar representation of the input signal sample.

In another exemplary embodiment, at least one power amplifier circuitry is configured to output power that is linearly proportional to another of the set of power amplifier circuitry or at least one power amplifier circuitry is configured to output power that is non-linearly proportional to another of the set of power amplifier circuits.

In another exemplary embodiment, the set of bandpass components includes a certain IF or RF signal.

In another exemplary embodiment, each bandpass component corresponds to one of the set of power amplifier circuitry, one of the set of quantization bits that represents the quantized amplitude of the polar representation of the input signal sample, and a phase of the polar representation of the input signal sample.

In another exemplary embodiment, the set of quantization bits of the quantized amplitude of the input signal sample is represented by three bits and the set of bandpass modulator circuitry is represented by two bandpass modulator circuitry.

In another exemplary embodiment, the set of quantization bits of the quantized amplitude of the input signal sample is represented by four bits and the set of bandpass modulator circuitry is represented by two bandpass modulator circuitry.

In another exemplary embodiment, at least one of the set of bandpass modulator circuitry has two outputs with each output being electrically coupled to an input of one of the set of power amplifier circuitry.

In another exemplary embodiment, at least one of the set of bandpass modulator circuitry is electrically coupled to a switch circuitry operable to selectively couple an output of each bandpass modulator circuitry to an input of one of the set of power amplifier circuitry.

In another exemplary embodiment, each bandpass modulator circuitry is a quadrature modulator circuitry or a quadrature digital to DAC circuitry.

In one exemplary embodiment, a user equipment device includes a set of bandpass modulator circuitry operable to output a punctured set of bandpass components that collectively represents a sample of an input signal having information and a set of power amplifier circuitry electrically coupled to the set of bandpass modulator circuitry and operable to amplify the punctured set of bandpass components. Further, the punctured set of bandpass components corresponds to the set of power amplifier circuitry and is associated with a set of quantized bits that represents a quantized amplitude of a polar representation of the input signal sample. In addition, the number of the set of bandpass modulator circuitry is less than the number of the set of quantized bits that represents that quantized amplitude.

The previous detailed description is merely illustrative in nature and is not intended to limit the present disclosure, or the application and uses of the present disclosure. Furthermore, there is no intention to be bound by any expressed or implied theory presented in the preceding field of use, background, summary, or detailed description. The present disclosure provides various examples, embodiments and the like, which may be described herein in terms of functional or logical block elements. The various aspects described herein are presented as methods, devices (or apparatus), systems, or articles of manufacture that may include a number of components, elements, members, modules, nodes, peripherals, or the like. Further, these methods, devices, systems, or articles of manufacture may include or not include additional components, elements, members, modules, nodes, peripherals, or the like.

Furthermore, the various aspects described herein may be implemented using standard programming or engineering techniques to produce software, firmware, hardware (e.g., circuits), or any combination thereof to control a computing device to implement the disclosed subject matter. It will be appreciated that some embodiments may be comprised of one or more generic or specialized processors such as microprocessors, digital signal processors, customized processors and FPGAs and unique stored program instructions (including both software and firmware) that control the one or more processors to implement, in conjunction with certain non-processor circuits, some, most, or all of the functions of the methods, devices and systems described herein. Alternatively, some or all functions could be implemented by a state machine that has no stored program instructions, or in one or more ASICs, in which each function or some combinations of certain of the functions are implemented as custom logic circuits. Of course, a combination of the two approaches may be used. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The term “article of manufacture” as used herein is intended to encompass a computer program accessible from any computing device, carrier, or media. For example, a computer-readable medium may include: a magnetic storage device such as a hard disk, a floppy disk or a magnetic strip; an optical disk such as a CD or DVD; a smart card; and a flash memory device such as a card, stick or key drive. Additionally, it should be appreciated that a carrier wave may be employed to carry computer-readable electronic data including those used in transmitting and receiving electronic data such as electronic mail (e-mail) or in accessing a computer network such as the Internet or a LAN. Of course, a person of ordinary skill in the art will recognize many modifications may be made to this configuration without departing from the scope or spirit of the subject matter of this disclosure.

Throughout the specification and the embodiments, the following terms take at least the meanings explicitly associated herein, unless the context clearly dictates otherwise. Relational terms such as “first” and “second,” and the like may be used solely to distinguish one entity or action from another entity or action without necessarily requiring or implying any actual such relationship or order between such entities or actions. The term “or” is intended to mean an inclusive “or” unless specified otherwise or clear from the context to be directed to an exclusive form. Further, the terms “a,” “an,” and “the” are intended to mean one or more unless specified otherwise or clear from the context to be directed to a singular form. The term “include” and its various forms are intended to mean including but not limited to. References to “one embodiment,” “an embodiment,” “example embodiment,” “various embodiments,” and other like terms indicate that the embodiments of the disclosed technology so described may include a particular function, feature, structure, or characteristic, but not every embodiment necessarily includes the particular function, feature, structure, or characteristic. Further, repeated use of the phrase “in one embodiment” does not necessarily refer to the same embodiment, although it may. The terms “substantially,” “essentially,” “approximately,” “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. A device or structure that is “configured” in a certain way is configured in at least that way, but may also be configured in ways that are not listed.

What is claimed is:

1. A method, comprising:
by a user equipment device having a set of bandpass modulator circuitry electrically coupled to a set of power amplifier circuitry,
outputting, by the set of bandpass modulator circuitry, a punctured set of bandpass components that collectively represents a sample of an input signal having information;
amplifying, by the set of power amplifier circuitry, the punctured set of bandpass components; and
wherein the punctured set of bandpass components corresponds to the set of power amplifier circuitry and is associated with a set of quantized bits that represents a quantized amplitude of a polar representation of the input signal sample, with a number of the set of bandpass modulator circuitry being less than a number of the set of quantized bits that represents that quantized amplitude.

2. The method of claim 1, wherein each bandpass component is associated with one of the set of quantization bits that represents the quantized amplitude of the polar representation of the input signal sample.

3. The method of claim 1, wherein at least one power amplifier circuitry is configured to output power that is linearly proportional to another of the set of power amplifier circuitry or at least one power amplifier circuitry is configured to output power that is non-linearly proportional to another of the set of power amplifier circuits.

4. The method of claim 1, wherein the set of bandpass components includes a certain intermediate frequency (IF) or radio frequency (RF) signal.

5. The method of claim 1, wherein each bandpass component corresponds to one of the set of power amplifier circuitry, one of the set of quantization bits that represents the quantized amplitude of the polar representation of the input signal sample, and a phase of the polar representation of the input signal sample.

6. The method of claim 1, wherein the set of quantization bits of the quantized amplitude of the input signal sample is represented by three bits and the set of bandpass modulator circuitry is represented by two bandpass modulator circuitry.

7. The method of claim 1, wherein the set of quantization bits of the quantized amplitude of the input signal sample is represented by four bits and the set of bandpass modulator circuitry is represented by two bandpass modulator circuitry.

8. The method of claim 1, wherein at least one of the set of bandpass modulator circuitry has two outputs with each output being electrically coupled to an input of one of the set of power amplifier circuitry.

9. The method of claim 1, wherein at least one of the set of bandpass modulator circuitry is electrically coupled to a switch circuitry operable to selectively couple an output of each bandpass modulator circuitry to an input of one of the set of power amplifier circuitry.

10. The method of claim 1, wherein each bandpass modulator circuitry is a quadrature modulator circuitry or a quadrature digital to analog converter (DAC) circuitry.

11. A user equipment device, comprising:
a set of bandpass modulator circuitry operable to output a punctured set of bandpass components that collectively represents a sample of an input signal having information;
a set of power amplifier circuitry electrically coupled to the set of bandpass modulator circuitry and operable to amplify the punctured set of bandpass components; and
wherein the punctured set of bandpass components corresponds to the set of power amplifier circuitry and is associated with a set of quantized bits that represents a quantized amplitude of a polar representation of the input signal sample, with a number of the set of bandpass modulator circuitry being less than a number of the set of quantized bits that represents that quantized amplitude.

12. The device of claim 11, wherein each bandpass component is associated with one of the set of quantization bits that represents the quantized amplitude of the polar representation of the sample.

13. The device of claim 11, wherein at least one power amplifier circuitry is configured to output power that is linearly proportional to another of the set of power amplifier circuitry or at least one power amplifier circuitry is configured to output power that is non-linearly proportional to another of the set of power amplifier circuits.

14. The device of claim 11, wherein the set of bandpass components includes a certain intermediate frequency (IF) or radio frequency (RF) signal.

15. The device of claim 11, wherein each component corresponds to one of the set of power amplifier circuitry, one of the set of quantization bits that represents the quantized amplitude of the polar representation of the sample, and a phase of the polar representation of the input sample.

16. The device of claim 11, wherein the set of quantization bits of the quantized amplitude of the input signal sample is represented by three bits and the set of bandpass modulator circuitry is represented by two bandpass modulator circuitry.

17. The device of claim 11, wherein the set of quantization bits of the quantized amplitude of the input signal sample is represented by four bits and the set of bandpass modulator circuitry is represented by two bandpass modulator circuitry.

18. The device of claim 11, wherein at least one of the set of bandpass modulator circuitry has two outputs with each output being electrically coupled to an input of one of the set of power amplifier circuitry.

19. The device of claim 11, wherein at least one of the set of bandpass modulator circuitry is electrically coupled to a switch circuitry operable to selectively couple an output of each bandpass modulator circuitry to an input of one of the set of power amplifier circuitry.

20. The device of claim 11, wherein each bandpass modulator circuitry is a quadrature modulator circuitry or a quadrature digital to analog converter (DAC) circuitry.
